(19) United States
(12) Patent Application Publication
(10) Pub. No.: US 2022/0406596 A1
(43) Pub. Date: Dec. 22, 2022

(54) METHOD FOR TREATING OBJECT TO BE TREATED AND TREATMENT LIQUID

(71) Applicant: FUJIFILM Corporation, Tokyo (JP)

(72) Inventors: Atsushi MIZUTANI, Shizuoka (JP); Yasuo SUGISHIMA, Shizuoka (JP)

(73) Assignee: FUJIFILM Corporation, Tokyo (JP)

(21) Appl. No.: 17/889,136

(22) Filed: Aug. 16, 2022

Related U.S. Application Data
(63) Continuation of application No. PCT/JP2021/002764, filed on Jan. 27, 2021.

(30) Foreign Application Priority Data
Feb. 18, 2020 (JP) 2020-024924

(51) Int. Cl. H01L 21/02

(52) U.S. Cl. CPC H01L 21/02244; H01L 21/02343

(57) ABSTRACT

An object of the present invention is to provide a treatment method excellently flattens an object to be treated in a case where the treatment method is applied to an object to be treated having a metal layer. Another object of the present invention is to provide a treatment liquid for an object to be treated. The method for treating an object to be treated according to an embodiment of the present invention is a method for treating an object to be treated having a step A of performing an oxidation treatment on an object to be treated having a metal layer so as to form a metal oxide layer and a step B of bringing a treatment liquid into contact with the object to be treated obtained by the step A so as to dissolve and remove the metal oxide layer, in which the treatment liquid contains an organic solvent and an acidic compound, and a content of the organic solvent is 50% by mass or more with respect to a total mass of the treatment liquid.

### CROSS-REFERENCE TO RELATED APPLICATIONS

This application is a Continuation of PCT International Application No. PCT/JP2021/002764 filed on Jan. 27, 2021, which claims priority under 35 U.S.C. § 119(a) to Japanese Patent Application No. 2020-024924 filed on Feb. 18, 2020. The above application is hereby expressly incorporated by reference, in its entirety, into the present application.

### BACKGROUND OF THE INVENTION

### 1. Field of the Invention

The present invention relates to a method for treating an object to be treated and a treatment liquid.

### 2. Description of the Related Art

With the progress of miniaturization of semiconductor devices, the etching treatment with a treatment liquid used in the semiconductor device manufacturing process is increasingly required to be more accurately performed with high efficiency.

For example, JP2019-061978A describes an invention relating to “a substrate treatment method of treating a substrate having a metal layer on a surface, the substrate treatment method including a metal oxide layer forming step of forming a metal oxide layer consisting of one atomic layer or several atomic layers on a surface layer of the metal layer by supplying an oxidizing fluid to a surface of the substrate and a metal oxide layer removing step of selectively removing the metal oxide layer from the surface of the substrate by supplying an etchant to the surface of the substrate”.

### SUMMARY OF THE INVENTION

The inventors of the present invention examined the substrate treatment method described in JP2019-061978A. As a result, the inventors have found that after the implementation of the treatment method of forming a metal oxide layer on an object to be treated having a metal layer and removing the metal oxide layer by bringing an etchant into contact with the formed metal oxide layer, the surface of the metal layer exposed due to the removal of the metal oxide layer is roughened, which sometimes leads to the deterioration of surface flatness of the metal layer (hereinafter, also simply described as “flatness of the metal layer”), and there is a room for further improvement in this method.

The present invention has been accomplished by taking the above circumstances in consideration, and an object thereof is to provide a treatment method excellently flattens an object to be treated in a case where the treatment method is applied to an object to be treated having a metal layer.

Another object of the present invention is to provide a treatment liquid for an object to be treated.

In order to achieve the above objects, the inventors of the present invention conducted intensive studies. As a result, the inventors have found that the objects can be achieved by the following constitutions.

[1]

A method for treating an object to be treated including a step A of performing an oxidation treatment on an object to be treated having a metal layer so as to form a metal oxide layer and a step B of bringing a treatment liquid into contact with the object to be treated obtained by the step A so as to dissolve and remove the metal oxide layer, in which the treatment liquid contains an organic solvent and an acidic compound, and a content of the organic solvent is 50% by mass or more with respect to a total mass of the treatment liquid.

[2]

The method for treating an object to be treated described in [1], in which the oxidation treatment is a treatment of bringing an oxidant into contact with the object to be treated having a metal layer.

[3]

The method for treating an object to be treated described in [1] or [2], in which the metal layer contains cobalt as a main component.

[4]

The method for treating an object to be treated described in any one of [1] to [3], in which the content of the organic solvent is 70% by mass or more with respect to the total mass of the treatment liquid.

[5]

The method for treating an object to be treated described in any one of [1 ] to [4], in which a content of water in the treatment liquid is 20% by mass or less with respect to the total mass of the treatment liquid.

[6]

The method for treating an object to be treated described in any one of [1] to [5], in which a content of water in the treatment liquid is 15% by mass or less with respect to the total mass of the treatment liquid.

[7]

The method for treating an object to be treated described in any one of [1] to [6], in which the treatment liquid substantially does not contain water.

[8]

The method for treating an object to be treated described in any one of [1] to [7], in which a content of the acidic compound is 30% by mass or less with respect to the total mass of the treatment liquid.

[9]

The method for treating an object to be treated described in any one of [1] to [8], in which the acidic compound includes an organic carboxylic acid.

[10]

The method for treating an object to be treated described in any one of [1] to [9], in which the organic solvent includes a neutral organic solvent.

[11]

The method for treating an object to be treated described in any one of [1] to [10], in which the organic solvent includes at least one solvent selected from the group consisting of an alcohol-based solvent, an ether-based solvent, an ester-based solvent, and a ketone-based solvent.

[12]

The method for treating an object to be treated described in any one of [1] to [11], in which the organic solvent includes an alkylene glycol dialkyl ether.

[13]

The method for treating an object to be treated described in any one of [1] to [12], in which a total content of Ni and Cu in the treatment liquid is 10 ppb by mass or less with respect to the total mass of the treatment liquid.

[14]

The method for treating an object to be treated described in any one of [1] to [13], in which the step A is a step of performing an oxidation treatment of bringing an oxidizing liquid into contact with the object to be treated having a metal layer so as to oxidize a surface layer of the metal layer and to form the metal oxide layer.

[15]

The method for treating an object to be treated described in [14], in which the oxidizing liquid is at least one liquid selected from the group consisting of water, hydrogen peroxide water, a mixed aqueous solution of ammonia and hydrogen peroxide, a mixed aqueous solution of hydrofluoric acid and hydrogen peroxide water, a mixed aqueous solution of sulfuric acid and hydrogen peroxide water, a mixed aqueous solution of hydrochloric acid and hydrogen peroxide water, water containing dissolved oxygen, water containing dissolved ozone, perchloric acid, and nitric acid.

[16]

The method for treating an object to be treated described in any one of [1] to [15], in which the step A and the step B are repeated.

[17]

A treatment liquid for an object to be treated having a metal oxide layer, the treatment liquid containing an organic solvent and an acidic compound, in which a content of the organic solvent is 50% by mass or more with respect to a total mass of the treatment liquid.

[18]

The treatment liquid described in [17], in which the metal oxide layer contains a cobalt oxide as a main component.

[19]

The treatment liquid described in [17] or [18], in which the content of the organic solvent is 70% by mass or more with respect to the total mass of the treatment liquid.

[20]

The treatment liquid described in any one of [17] to [19], in which a content of water in the treatment liquid is 20% by mass or less with respect to the total mass of the treatment liquid.

[21]

The treatment liquid described in any one of [17] to [20], in which a content of water is 10% by mass or less with respect to the total mass of the treatment liquid.

[22]

The treatment liquid described in any one of [17] to [21], in which the treatment liquid substantially does not contain water.

[23]

The treatment liquid described in any one of [17] to [22], in which a content of the acidic compound is 30% by mass or less with respect to the total mass of the treatment liquid.

[24]

The treatment liquid described in any one of [17] to [23], in which the acidic compound includes an organic carboxylic acid.

[25]

The treatment liquid described in any one of [17] to [24], in which the organic solvent includes a neutral organic solvent.

[26]

The treatment liquid described in any one of [17] to [25], in which the organic solvent includes at least one solvent selected from the group consisting of an alcohol-based solvent, an ether-based solvent, an ester-based solvent, and a ketone-based solvent.

[27]

The treatment liquid described in any one of [17] to [26], in which the organic solvent includes an alkylene glycol dialkyl ether.

[28]

The treatment liquid described in any one of [17] to [27], in which a total content of Ni and Cu is 10 ppb by mass or less with respect to the total mass of the treatment liquid.

According to an aspect of the present invention, it is possible to provide a treatment method excellently flattening an object to be treated in a case where the treatment method is applied to an object to be treated having a metal layer.

Furthermore, according to an aspect of the present invention, it is possible to provide a treatment liquid for an object to be treated.

### BRIEF DESCRIPTION OF THE DRAWINGS

FIG. 1 is a cross-sectional view showing an example of an embodiment of an object to be treated.

FIG. 2 is a cross-sectional view showing another example of the embodiment of the object to be treated.

### DESCRIPTION OF THE PREFERRED EMBODIMENTS

Hereinafter, the present invention will be specifically described.

The following constituents will be described based on typical embodiments of the present invention in some cases, but the present invention is not limited to the embodiments.

In the present specification, the range of numerical values described using “to” means a range including the numerical values listed before and after “to” as the lower limit and the upper limit.

In the present specification, in a case where there are two or more kinds of components corresponding to a certain component, “content” of such a component means the total content of the two or more kinds of components.

Furthermore, in the present specification, “ppm” means “parts-per-million (10⁻⁶)”, “ppb” means “parts-per-billion (10⁻⁹)”, and “ppt” means “parts-per-trillion (10⁻¹²)”.

In the present specification, “room temperature” is “25° C.”.

### Method for Treating Object to be Treated

The method for treating an object to be treated according to an embodiment of the present invention (hereinafter, also described as “the present treatment method”) includes a step A of performing an oxidation treatment on an object to be treated having a metal layer so as to form a metal oxide layer and a step B of bringing a specific treatment liquid into contact with the object to be treated obtained by the step A so as to dissolve and remove the metal oxide layer.

The mechanism by which the treatment method according to the embodiment of the present invention constituted as above achieves the aforementioned objects is unclear. According to the inventors of the present invention, the mechanism is considered to be as below.

That is, in the treatment liquid used in the step B of removing the metal oxide layer in the present treatment method (hereinafter, the treatment liquid will be also described as “the present treatment liquid”), the content of an organic solvent is 50% by mass or more with respect to the total mass of the treatment liquid. Presumably, because the organic solvent at such a high content functions to protect the exposed metal layer in the step B and suppresses the dissolution and removal of the metal layer, the etching amount of the metal layer may be inhibited from varying in the in-plane direction, and the surface of the metal layer may further flatten after the treatment.

Hereinafter, regarding the present invention, the further improvement of smoothness of an object to be treated will be also described as “further improving the effect of the present invention”.

Hereinafter, the treatment liquid used in the step B of the present treatment method and the object to be treated applied to the present treatment method will be described, and then each step of the present treatment method will be described.

### Treatment Liquid

The present treatment liquid contains an organic solvent and an acidic compound, and the content of the organic solvent is 50% by mass or more with respect to the total mass of the treatment liquid.

As will be described later, the present treatment liquid is a treatment liquid for an object to be treated having a metal oxide layer.

### Organic Solvent

The present treatment liquid contains an organic solvent. The organic solvent is not particularly limited as long as it is an organic compound that is a liquid at room temperature (25° C.) and 1 atm.

Examples of the organic solvent include an alcohol-based solvent, an ether-based solvent, a ketone-based solvent, an ester-based solvent, a sulfone-based solvent, a sulfoxide-based solvent, a nitrile-based solvent, and an amide-based solvent.

As the organic solvent, a neutral organic solvent is preferable. The neutral organic solvent refers to a solvent other than a protogenic solvent (acidic solvent) and a protophilic solvent (basic solvent). Examples of the neutral organic solvent include an alcohol-based solvent, an ether-based solvent, an ester-based solvent, a ketone-based solvent, a sulfoxide-based solvent, and an amide-based solvent.

The organic solvent may be water-soluble. For an organic solvent, “water-soluble” means that water at 25° C. and the organic solvent are miscible (dissolvable) at an arbitrary ratio.

The alcohol-based solvent is not particularly limited as long as it is a compound having a hydroxyl group. Examples thereof include an alkanediol, an alkoxy alcohol, a saturated aliphatic monohydric alcohol, an unsaturated non-aromatic monohydric alcohol, and an alcohol having a ring structure.

Examples of the alkanediol include ethylene glycol, propylene glycol, 2-methyl-1,3-propanediol, 1,3-propanediol, 2,2-dimethyl-1,3-propanediol, 1,4-butanediol, 1,3-butanediol, 1,2-butanediol, 2,3-butanediol, hexylene glycol, pinacol, diethylene glycol, dipropylene glycol, triethylene glycol, and tetraethylene glycol.

Examples of the alkoxy alcohol include 3-methoxy-3-methyl-1-butanol (MMB), 3-methoxy-1-butanol, 1-methoxy-2-butanol, and an alkylene glycol monoalkyl ether.

Examples of the alkylene glycol monoalkyl ether include ethylene glycol monomethyl ether, ethylene glycol monoethyl ether, ethylene glycol mono-n-propyl ether, ethylene glycol monoisopropyl ether, ethylene glycol monobutyl ether (EGBE), diethylene glycol monomethyl ether, diethylene glycol monoethyl ether, diethylene glycol monobutyl ether (DEGBE), triethylene glycol monomethyl ether, triethylene glycol monoethyl ether, triethylene glycol monobutyl ether, 1-methoxy-2-propanol, 2-methoxy-1-propanol, 1-ethoxy-2-propanol, 2-ethoxy-1-propanol, propylene glycol monomethyl ether, propylene glycol mono-n-propyl ether, dipropylene glycol monomethyl ether, dipropylene glycol monoethyl ether, dipropylene glycol mono-n-propyl ether, tripropylene glycol monoethyl ether, tripropylene glycol monomethyl ether, ethylene glycol mono benzyl ether, diethylene glycol monobenzyl ether, 1-octanol, 2-octanol, and 2-ethylhexanol.

Among these, 3-methoxy-3-methyl-1-butanol (MMB) or an alkylene glycol monoalkyl ether is preferable, and ethylene glycol monobutyl ether (EGBE) or diethylene glycol monobutyl ether (DEGBE) is more preferable.

Examples of the saturated aliphatic monohydric alcohol include methanol, ethanol, n-propyl alcohol, isopropyl alcohol, 1-butanol, 2-butanol, isobutyl alcohol, tert-butyl alcohol, 2-pentanol, t-pentyl alcohol, and hexanol.

Examples of the unsaturated non-aromatic monohydric alcohol include allyl alcohol, propargyl alcohol, 2-butenyl alcohol, 3-butenyl alcohol, and 4-penten-2-ol.

Examples of the alcohol having a ring structure include tetrahydrofurfuryl alcohol, furfuryl alcohol, benzyl alcohol, and 1,3-cyclopentanediol.

As the alcohol-based solvent, an alkanediol, an alkoxyalcohol, or an alcohol having a ring structure is preferable, and an alkylene glycol monoalkyl ether is more preferable.

The number of hydroxyl groups contained in the alcohol-based solvent is not particularly limited, but is preferably 1 to 3 and more preferably 1 or 2.

The number of carbon atoms in the alcohol-based solvent is not particularly limited, and is preferably 2 to 12 and more preferably 3 to 10.

The ether-based solvent is a compound that has an ether bond (—O—) but does not have a hydroxyl group and an ester bond (—C(═O)—O—).

The ether-based solvent is not particularly limited, and examples thereof include diethyl ether, diisopropyl ether, dibutyl ether, t-butyl methyl ether, cyclohexyl methyl ether, tetrahydrofuran, and an alkylene glycol dialkyl ether. Among these, an alkylene glycol dialkyl ether is preferable.

Examples of the alkylene glycol dialkyl ether include diethylene glycol diethyl ether (DEGDEE), diethylene glycol dipropyl ether, diethylene glycol dibutyl ether, triethylene glycol diethyl ether, tetraethylene glycol dimethyl ether (tetraglyme), tetraethylene glycol diethyl ether, ethylene glycol dimethyl ether, diethylene glycol dimethyl ether, and triethylene glycol dimethyl ether.

The number of carbon atoms in the ether-based solvent is not particularly limited, but is preferably 3 to 16, more preferably 4 to 14, and even more preferably 6 to 12.

The ester-based solvent is not particularly limited as long as it is a compound having an ester bond (—C(═O)—O—). Examples thereof include ethyl acetate, butyl acetate, glycol monoesters such as ethylene glycol monoacetate and diethylene glycol monoacetate; glycol monoether monoesters such as propylene glycol monomethyl ether acetate, ethylene glycol monomethyl ether acetate, propylene glycol monoethyl ether acetate (PGMEA), and ethylene glycol monoethyl ether acetate; glycol diesters such as ethylene glycol diacetate and propylene glycol diacetate (PGDA); and cyclic esters such as propylene carbonate, ethylene carbonate (ethylene carbonate), and diethyl carbonate (diethyl carbonate).

The number of carbon atoms in the ester-based solvent is not particularly limited, but is preferably 2 to 10 and more preferably 2 to 6.

The ketone-based solvent is not particularly limited as long as it is a compound that has a carbonyl group (—C(═O)—) and is not included in the aforementioned ester-based solvent. Examples thereof include acetone, dimethyl ketone (propanone), cyclobutanone, cyclopentanone, cyclohexanone, diacetone alcohol, methyl ethyl ketone (2-butanone), 5-hexanedione, methyl isobutyl ketone, 1,4-cyclohexanedione, and 1,3-cyclohexanedione.

Examples of the sulfone-based solvent include sulfolane, 3-methylsulfolane, and 2,4-dimethylsulfolane.

Examples of the sulfoxide-based solvent include dimethyl sulfoxide.

Examples of the nitrile-based solvent include acetonitrile.

Examples of the amide-based solvent include N,N-dimethylformamide, 1-methyl-2-pyrrolidone, 2-pyrrolidinone, 1,3-dimethyl-2-imidazolidinone, ε-caprolactam, formamide, N-methylformamide, acetamide, N-methylacetamide, N,N-dimethylacetamide, N-methylpropanamide, and hexamethylphosphoric triamide.

As the organic solvent, at least one solvent selected from the group consisting of an alcohol-based solvent, an ether-based solvent, an ester-based solvent, and a ketone-based solvent is preferable. In view of further improving the effect of the present invention, propylene carbonate, an alkylene glycol monoalkyl ether, or an alkylene glycol dialkyl ether is more preferable, and an alkylene glycol dialkyl ether is even more preferable.

One kind of organic solvent may be used alone, or two or more kinds of organic solvents may be used in combination.

The content of the organic solvent in the present treatment liquid is 50% by mass or more with respect to the total mass of the treatment liquid. The content of the organic solvent with respect to the total mass of the treatment liquid is preferably 70% by mass or more, and more preferably 90% by mass or more.

The upper limit of the content of the organic solvent is not particularly limited. The upper limit of the content of the organic solvent with respect to the total mass of the treatment liquid is preferably 99.9% by mass or less, and more preferably 99% by mass or less.

### Acidic Compound

The treatment liquid according to the embodiment of the present invention contains an acidic compound.

The acidic compound is not particularly limited as long as it is a compound showing acidity (pH of less than 7.0) in an aqueous solution, and may be either an inorganic acid or an organic acid.

Examples of the inorganic acid include sulfuric acid, hydrochloric acid, phosphoric acid, nitric acid, hydrobromic acid, hydrofluoric acid, perchloric acid, hypochlorous acid, and periodic acid. Among these, hydrobromic acid or hydrofluoric acid is preferable, and hydrofluoric acid is more preferable.

Examples of organic acid include an organic carboxylic acid and an organic sulfonic acid.

Examples of the organic carboxylic acid include lower (having 1 to 4 carbon atoms) aliphatic monocarboxylic acids such as formic acid, acetic acid, propionic acid, and butyric acid; lower (having 1 to 4 carbon atoms) aliphatic dicarboxylic acids such as oxalic acid, malonic acid, and succinic acid; hydroxyl group-containing lower (having 1 to 4 carbon atoms) hydroxy acids such as glycolic acid, malic acid, tartaric acid, and citric acid; and aromatic carboxylic acids such as benzoic acid.

Examples of the organic sulfonic acid include methanesulfonic acid (MSA), benzenesulfonic acid, and p-toluenesulfonic acid (tosylic acid).

The number of acidic groups contained in the acidic compound is not particularly limited, but is preferably 1 to 5.

In a case where the acidic compound is an organic acid, the number of carbon atoms in the organic acid is not particularly limited, but is preferably 2 to 20 and more preferably 2 to 8.

As the acidic compound, in view of further improving the effect of the present invention, an organic carboxylic acid is preferable, a lower aliphatic dicarboxylic acid or a lower hydroxy acid is more preferable, and oxalic acid, malonic acid, citric acid, malic acid, or tartaric acid is even more preferable.

One kind of acidic compound may be used alone, or two or more kinds of acidic compounds may be used in combination. As the acidic compound, a salt of the acidic compound may also be used as long as the salt turns into an acid or an acid ion (anion) in an aqueous solution. As the acidic compound, a commercially available acidic compound or an acidic compound appropriately synthesized by a known method may also be used.

The content of the acidic compound with respect to the total mass of the treatment liquid is preferably 40% by mass or less, more preferably 30% by mass or less, and even more preferably 10% by mass or less. The lower limit of the content of the acidic compound is not particularly limited. In view of more satisfactory etching amount of the acidic metal layer, the content of the acidic compound with respect to the total mass of the treatment liquid is preferably 0.1% by mass or more, and more preferably 1.0% by mass or more.

### Water

The present treatment liquid may contain water.

The water is not particularly limited, and examples thereof include distilled water, deionized water, and pure water.

The content of water in the treatment liquid is not particularly limited. In view of further improving the effect of the present invention, the content of water with respect to the total mass of the treatment liquid is preferably 20% by mass or less, more preferably 15% by mass or less, and even more preferably 5% by mass or less.

It is particularly preferable that the treatment liquid substantially do not contain water. In the present specification, “substantially do not contain water” means that the content of water is 0.5% by mass or less with respect to the total mass of the treatment liquid. In the treatment liquid, the content of water is most preferably 0.01% by mass or less with respect to the total mass of the treatment liquid. The lower limit of the content of water is not particularly limited, and may be 0% by mass.

### Optional Components

The present treatment liquid may optionally contain other components in addition to the above components.

Examples of those other components that the present treatment liquid may contain include an anticorrosive, a metal component, and a pH adjuster.

### Anticorrosive

The treatment liquid may contain an anticorrosive. The anticorrosive is preferable because this component further improves the effect of the present invention by suppressing overetching of the metal layer exposed in the step B.

Examples of the anticorrosive include an azole compound. The azole compound is a compound having at least one nitrogen atom and a 5-membered aromatic heterocycle.

The number of nitrogen atoms contained in the 5-membered heterocycle of the azole compound is not particularly limited, and is preferably 1 to 4 and more preferably 2 to 4.

Examples of the azole compound include an imidazole compound in which one of the atoms constituting the azole ring is a nitrogen atom, a pyrazole compound in which two of the atoms constituting the azole ring are nitrogen atoms, a thiazole compound in which one of the atoms constituting the azole ring is a nitrogen atom and the other is a sulfur atom, a triazole compound in which three of the atoms constituting the azole ring are nitrogen atoms, and a tetrazole compound in which four of the atoms constituting the azole ring are nitrogen atoms.

Examples of the imidazole compound include imidazole, 1-methylimidazole, 2-methylimidazole, 5-methylimidazole, 1,2-dimethylimidazole, 2-mercaptoimidazole, 4,5-dimethyl-2-mercaptoimidazole, 4-hydroxyimidazole, 2,2′-biimidazole, 4-imidazole carboxylic acid, histamine, and benzimidazole.

Examples of the pyrazole compound include pyrazole, 4-pyrazolecarboxylic acid, 1-methylpyrazole, 3-methylpyrazole, 3-amino-5-hydroxypyrazole, 3-aminopyrazole, and 4-aminopyrazole.

Examples of the thiazole compound include 2,4-dimethylthiazole, benzothiazole, and 2-mercaptobenzothiazole.

Examples of the triazole compound include a benzotriazole formed in a case where two adjacent substituents on a triazole ring are bonded and form a benzene ring.

Examples of the benzotriazole compound include benzotriazole, 5-methyl-1H-benzotriazole (CAS registry number: 136-85-6), tolyl triazole (CAS registry number: 29385-43-1), 5-aminobenzotriazole, 1-hydroxybenzotriazole, 4-carboxybenzotriazole, 5,6-dimethylbenzotriazole, 1-[N,N-bis(hydroxyethyl)aminoethyl]benzotriazole, 1-(1,2-dicarboxyethyl)benzotriazole, 1-[N,N-bis(2-ethylhexyl)aminomethyl]benzotriazole, 1-[N,N-bis(2-ethylhexyl)aminomethyl]methylbenzotriazole, 2,2′-{[(methyl-1H-benzotriazol-1-yl)methyl]imino}bisethanol, and carboxybenzotriazole.

Examples of triazol compounds other than the benzotriazole compound include 1,2,3-triazole, 1,2,4-triazole, 3-methyl-1,2,4-triazol, 3-amino-1,2,4-triazole, and 1-methyl-1,2,3-triazol.

Examples of the tetrazole compound include 11-1-tetrazole (1,2,3,4-tetrazole), 5-methyl-1,2,3,4-tetrazole, 5-amino-1,2,3,4-tetrazole, 1,5-pentamethylenetetrazole, 1-phenyl-5-mercaptotetrazole, and 1-(2-dimethylaminoethyl)-5-mercaptotetrazole.

As the azole compound, a triazole compound or a tetrazole compound is preferable, and a triazole compound is more preferable.

In the present specification, the aforementioned azole compound includes a tautomer thereof.

The present treatment liquid may contain an anticorrosive other than the azole compound.

Examples of the anticorrosive other than the azole compound include nitrogen-containing heterocyclic compounds such as 2,4-diamino-6-methyl-1,3,5-triazine, triazine, diaminomethyltriazine, imidazoline thione, 2,3,5-trimethylpyrazine,2-ethyl-3,5-dimethylpyrazine, quinoxaline, acetylpyrrole, pyridazine, and pyrazine, saccharides such as fructose, glucose, and ribose, polyvinylpyrrolidone, adenosine and derivatives thereof, purine compounds and derivatives thereof, phenanthroline, resorcinol, hydroquinone, nicotinamide and derivatives thereof, flavonols and derivatives thereof, anthocyanin and derivatives thereof, and combinations of these.

As the anticorrosive, an azole compound or hydroquinone is preferable, and a triazole compound or hydroquinone is more preferable.

One kind of anticorrosive may be used alone, or two or more kinds of anticorrosives may be used in combination.

In a case where the treatment liquid contains an anticorrosive, the content of the anticorrosive with respect to the total mass of the treatment liquid is preferably 0.01% to 10% by mass, and more preferably 0.02% to 2% by mass.

### Metal Component

The treatment liquid may contain a metal component.

Examples of the metal component include metal particles and metal ions. For example, the content of the metal component means the total content of metal particles and metal ions. Furthermore, the metal particles may be a simple metal or an alloy, and may be in the form of particles in which a metal and an organic substance are aggregated.

Examples of the metal atom contained in the metal component include metal atoms selected from the group consisting of Ag, Al, As, Au, Ba, Ca, Cd, Co, Cr, Cu, Fe, Ga, Ge, K, Li, Mg, Mn, Mo, Na, Ni, Pb, Sn, Sr, Ti, and Zn.

The metal component may contain one kind of metal atom or two or more kinds of metal atoms.

The metal component contained in the present treatment liquid may be a metal component which is inevitably incorporated into each component (raw material) or a metal component inevitably incorporated into the treatment liquid during the manufacturing, storage, and/or transfer of the treatment liquid.

In a case where the treatment liquid contains a metal component, the content of the metal component with respect to the total mass of the treatment liquid is usually more than 0 ppt by mass and 10 ppm by mass or less, preferably more than 0 ppm by mass and 1 ppm by mass or less, and more preferably more than 0 ppb by mass and 100 ppb by mass or less.

The type and content of the metal component in the treatment liquid can be measured by the Single Nano Particle Inductively Coupled Plasma Mass Spectrometry (SP-ICP-MS).

Especially, in view of making it possible to further suppress pitting and corrosion of the surface of an object to be treated after treatment, the total content of Ni and Cu in the treatment liquid with respect to the total mass of the treatment liquid is preferably 50 ppb by mass or less, and more preferably 10 ppb by mass or less. The lower limit of the total content of Ni and Cu is not particularly limited, and may be 0 ppb by mass.

Furthermore, the total content of metals that are more noble than the metal contained as a main component in the metal layer of the object to be treated is preferably 50 ppb by mass or less and more preferably 10 ppb by mass or less, with respect to the total mass of the treatment liquid. For example, in a case where the metal contained as a main component in the metal layer of the object to be treated is cobalt, the total content of metals (that is, nickel (Ni), tin (Sn), lead (Pb), antimony (Sb), bismuth (Bi), copper (Cu), mercury (Hg), silver (Ag), palladium (Pd), Iridium (1r), platinum (Pt), and gold (Au)) that are more noble than cobalt with respect to the total mass of the treatment liquid is preferably 50 ppb by mass or less, and more preferably 10 ppb by mass or less.

### pH Adjuster (Basic Compound)

The present treatment liquid may contain a basic compound as a pH adjuster. Furthermore, the aforementioned acidic compound may be allowed to function as a pH adjuster.

Examples of the basic compound include aqueous ammonia, an amine compound, and a quaternary ammonium salt.

As the amine compound, a water-soluble amine having a pka of 7.5 to 13.0 at room temperature is preferable. In the present specification, the water-soluble amine means an amine compound which can dissolve in an amount of 50 g or more in 1 L of water at room temperature. In addition, aqueous ammonia is not included in the water-soluble amine.

Examples of the water-soluble amine having a pKa of 7.5 to 13 include diglycolamine (DGA) (pKa=9.80), methylamine (pKa=10.6), ethylamine (pKa=10.6), propylamine (pKa=10.6), butylamine (pKa=10.6), pentylamine (pKa=10.0), ethanolamine (pKa=9.3), propanolamine (pKa=9.3), butanol amine (pKa=9.3), methoxyethylamine (pKa=10.0), methoxypropylamine (pKa=10.0), dimethylamine (pKa=10.8), diethylamine (pKa=10.9), dipropylamine (pKa=10.8), trimethylamine (pKa=9.80), and triethylamine (pKa=10.72).

In the present specification, the pka of the water-soluble amine is an acid dissociation constant in water. The acid dissociation constant in water can be measured using a spectrometer and potentiometry in combination.

Examples of the quaternary ammonium salt include a quaternary ammonium hydroxide represented by the following Formula (5).

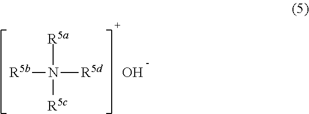

In Formula (5), R^{5a} to R^{5d} each independently represent an alkyl group having 1 to 16 carbon atoms, an aryl group having 6 to 16 carbon atoms, an aralkyl group having 7 to 16 carbon atoms, or a hydroxyalkyl group having 1 to 16 carbon atoms. At least two of R^{5a} to R^{5d} may be bonded to each other to form a cyclic structure. Particularly, the groups in at least either a combination of R^{5a} and R^{5b} or a combination of R^{5c} and R^{5d} may be bonded to each other to form a cyclic structure.

As the compound represented by Formula (5), tetramethylammonium hydroxide, tetraethylammonium hydroxide, tetrapropylammonium hydroxide, tetrabutylammonium hydroxide, methyltripropylammonium hydroxide, methyltributylammonium hydroxide, ethyltrimethylammonium hydroxide, dimethyldiethylammonium hydroxide, benzyltrimethylammonium hydroxide, hexadecyltrimethylammonium hydroxide, or (2-hydroxyethyl)trimethylammonium hydroxide is preferable.

In a case where the treatment liquid contains a basic compound, the content of the basic compound with respect to the total mass of the treatment liquid is preferably 0.01% to 10% by mass, and more preferably 0.1% to 5% by mass.

The content of each component in the treatment liquid can be measured by ion chromatography (Dionex ICS-2100 from Thermo Fisher Scientific Inc., or the like).

Furthermore, in a case where the components and formulation of the raw materials used for preparing the treatment liquid are known, the content of hydroxylamine may be calculated from the amount of the compound formulated.

### Treatment Liquid Manufacturing Method

The method for manufacturing the treatment liquid is not particularly limited, and known manufacturing methods can be used. Examples thereof include a method of mixing together an organic solvent, an acidic compound, and an anticorrosive agent and/or water. In mixing the above components, as necessary, other optional components may be mixed together.

Furthermore, in manufacturing the treatment liquid, as necessary, the treatment liquid may be purified by being filtered using a filter.

### Treatment Liquid Container

The treatment liquid may be stored in a container and kept as it is until use.

The container and the treatment liquid stored in the container are collectively called treatment liquid container. The stored treatment liquid is used after being taken out of the treatment liquid container. Furthermore, the treatment liquid may be transported as a treatment liquid container.

It is preferable to use a container for semiconductors which has a high internal cleanliness and hardly causes elution of impurities. Examples of usable containers include a “CLEAN BOTTLE” series manufactured by AICELLO CORPORATION, and “PURE BOTTLE” manufactured by KODAMA PLASTICS Co., Ltd.

It is preferable that the inner wall of the container be formed of one or more kinds of resins selected from the group consisting of a polyethylene resin, a polypropylene resin, and a polyethylene-polypropylene resin, or formed of a resin different from these. It is also preferable that the inner wall of the container be formed of a metal having undergone a rustproofing treatment or a metal elution preventing treatment, such as stainless steel, Hastelloy, Inconel, or Monel.

As “resin different from these” described above, a fluororesin (perfluororesin) is preferable. In a case where a container having inner wall made of a fluororesin is used, the occurrence of problems such as elution of an ethylene or propylene oligomer can be further suppressed, than in a case where a container having inner wall formed of a polyethylene resin, a polypropylene resin, or a polyethylene-polypropylene resin is used.

Examples of the container having inner wall made of a fluororesin include a FluoroPure PFA composite drum manufactured by Entegris. In addition, it is also possible to use the containers described on page 4 of JP1991-502677A (JP-H03-502677A), page 3 of WO2004/016526A, and pages 9 and 16 of W099/046309A.

Furthermore, in addition to the fluororesin described above, quartz and an electropolished metallic material (that is, a metallic material having undergone electropolishing) are also preferably used for the inner wall of the container.

For manufacturing the electropolished metallic material, it is preferable to use a metallic material which contains at least one kind of metal selected from the group consisting of chromium and nickel, and in which the total content of chromium and nickel is more than 25% by mass with respect to the total mass of the metallic material. Examples of such a metallic material include stainless steel and a nickel-chromium alloy.

The total content of chromium and nickel in the metallic material is preferably 30% by mass or more with respect to the total mass of the metallic material.

The upper limit of the total content of chromium and nickel in the metallic material is not particularly limited, but is preferably 90% by mass or less with respect to the total mass of the metallic material.

The stainless steel is not particularly limited, and known stainless steel can be used. Particularly, an alloy with a nickel content of 8% by mass or more is preferable, and austenite-based stainless steel with a nickel content of 8% by mass or more is more preferable.

Examples of the austenite-based stainless steel include Steel Use Stainless (SUS) 304 (Ni content: 8% by mass, Cr content: 18% by mass), SUS304L (Ni content: 9% by mass, Cr content: 18% by mass), SUS316 (Ni content: 10% by mass, Cr content: 16% by mass), and SUS316L (Ni content: 12% by mass, Cr content: 16% by mass).

The nickel-chromium alloy is not particularly limited, and known nickel-chromium alloys can be used. Among these, a nickel-chromium alloy is preferable in which the nickel content is 40% to 75% by mass and the chromium content is 1% to 30% by mass.

Examples of the nickel-chromium alloy include HASTELLOY (trade name, the same is true of the following description), MONEL (trade name, the same is true of the following description), and INCONEL (trade name, the same is true of the following description). More specifically, examples thereof include HASTELLOY C-276 (Ni content: 63% by mass, Cr content: 16% by mass), HASTELLOY C (Ni content: 60% by mass, Cr content: 17% by mass), and HASTELLOY C-22 (Ni content: 61% by mass, Cr content: 22% by mass).

Furthermore, as necessary, the nickel-chromium alloy may further contain boron, silicon, tungsten, molybdenum, copper, or cobalt, in addition to the aforementioned alloy.

The method of electropolishing the metallic material is not particularly limited, and known methods can be used. For example, it is possible to use the methods described in paragraphs “0011” to “0014” in JP2015-227501A and paragraphs “0036” to “0042” in JP2008-264929A.

It is preferable that the metallic material have undergone buffing. As the buffing method, known methods can be used without particular limitation. The size of abrasive grains used for finishing the buffing is not particularly limited, but is preferably # 400 or less because such grains make it easy to further reduce the surface asperity of the metallic material.

The buffing is preferably performed before the electropolishing.

Furthermore, one of the multistage buffing carried out by changing the size of abrasive grains, acid pickling, magnetorheological finishing, and the like or a combination of two or more treatments selected from the above may be performed on the metallic material.

It is preferable that the inside of these containers be washed before the containers are filled with the treatment liquid. For washing, it is preferable to use a liquid with a lower metal impurity content.

After being manufactured, the treatment liquid may be bottled using a container, such as a gallon bottle or a quart bottle, and transported or stored.

In order to prevent changes in the components of the treatment liquid during storage, the inside of the container may be purged with an inert gas (such as nitrogen or argon) having a purity of 99.99995% by volume or higher. Particularly, a gas with a low moisture content is preferable. Although the treatment liquid may be transported and stored at room temperature, in order to prevent deterioration, the temperature may be controlled in a range of −20° C. to 20° C.

The treatment liquid may be prepared as a kit composed of a plurality of separated raw materials of the treatment liquid. Examples of the kit include a kit containing a first liquid containing an organic solvent and a second liquid containing an acidic compound.

Furthermore, the treatment liquid may be prepared as a concentrated solution. In a case where the treatment liquid is prepared as a concentrated solution, the concentration factor is appropriately determined depending on the composition, but is preferably 5× to 2,000×. That is, the concentrated solution is used after being diluted 5× to 2,000×.

### Object to be Treated

The form of the object to be treated having a metal layer applied to the present treatment method (hereinafter, this object will be also simply described as “object to be treated”) is not particularly limited as long as it has a metal layer. Examples of the object to be treated include a substrate having a metal layer.

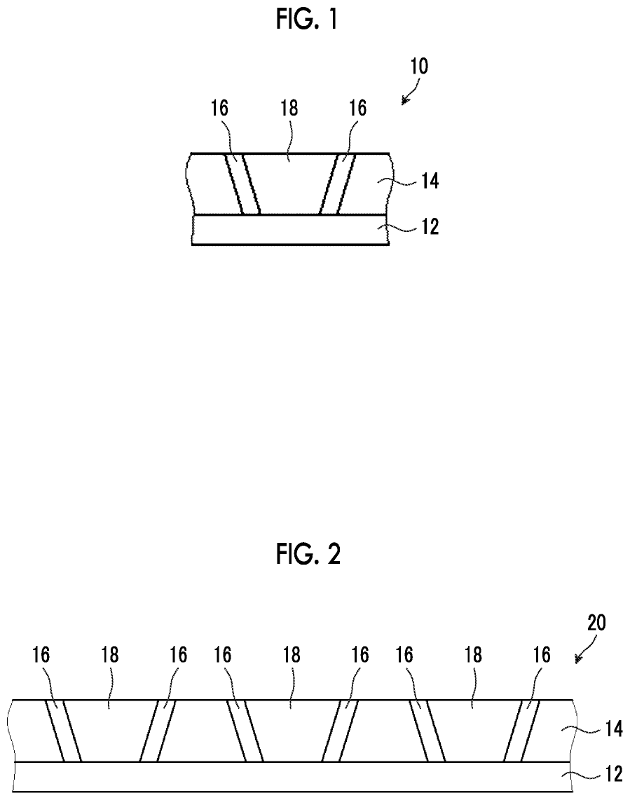

FIG. 1 is a cross-sectional view showing an example of the object to be treated applied to the present treatment method.

An object 10 to be treated shown in FIG. 1 has a substrate 12, an insulating film 14 that is disposed on the substrate 12 and has hole portions, a barrier layer 16 that is disposed in the form of a layer along the inner wall of each of the hole portions of the insulating film 14, and a metal-containing substance portion 18 with which the hole portions are filled.

FIG. 2 is a cross-sectional view showing another example of the object to be treated applied to the present treatment method.

An object 20 to be treated shown in FIG. 2 has a substrate 12, an insulating film 14 that is disposed on the substrate 12 and has a plurality of hole portions, a barrier layer 16 that is disposed in the form of a layer along the inner wall of each of the hole portions of the insulating film 14, and a metal layer 18 with which each of the hole portions is filled.

As shown in FIG. 2, the object to be treated may have an aspect in which the object to be treated has a metal layer over a plurality of sites.

Examples of the metal layer of the object to be treated include a simple metal and an alloy.

Examples of metal atoms contained in the metal layer include cobalt (Co), ruthenium (Ru), tungsten (W), molybdenum (Mo), aluminum (Al), copper (Cu), titanium (Ti), and tantalum (Ta).

The content of metal atoms in the metal layer with respect to the total mass of the metal layer is preferably 30% to 100% by mass, more preferably 40% to 100% by mass, and even more preferably 52% to 100% by mass.

The metal layer preferably contains cobalt, ruthenium, tungsten, molybdenum, aluminum, copper, titanium, or tantalum as a main component, more preferably contains cobalt or copper as a main component, and even more preferably contains cobalt as a main component.

In the present specification, for example, “contains cobalt as a main component” means that the content of cobalt is the highest among the metal atoms contained in the metal layer. Examples of the metal layer containing cobalt as a main component include simple cobalt (metallic cobalt) and a cobalt alloy (alloy containing cobalt as metal atoms at the highest content).

The content of metal atoms (preferably cobalt atoms) contained as a main component in the metal layer with respect to the total mass of the metal layer is preferably 50% to 100% by mass, more preferably 80% to 100% by mass, and even more preferably 95% to 100% by mass.

The form of the metal layer in the object to be treated is not particularly limited, and examples thereof include a metal layer disposed in the form of a film (metal-containing film) and a metal layer disposed in the form of a wiring line (metal-containing wiring line film).

In a case where the metal layer is in the form of a film or wiring line, the thickness thereof is not particularly limited and may be appropriately selected depending on the use. The thickness of the metal layer in the form of a film or wiring line is preferably 500 nm or less, more preferably 20 nm or less, and even more preferably 50 nm or less. The lower limit thereof is not particularly limited, but is preferably 1 nm or more.

The object to be treated may have the metal layer, for example, on only one of the main surfaces of the substrate or on both the main surfaces of the substrate. The metal layer may be disposed on the entire main surface of the substrate, or may be disposed on a portion of the main surface of the substrate.

In addition, the object to be treated may have two or more metal layers having different structures and/or compositions.

The type of substrate in the object to be treated is not particularly limited. Examples of the substrate include various substrates such as a semiconductor wafer, a glass substrate for a photomask, a glass substrate for liquid crystal display, a glass substrate for plasma display, a substrate for field emission display (FED), a substrate for an optical disk, a substrate for a magnetic disk, and a substrate for a magneto-optical disk.

Examples of materials constituting the semiconductor substrate include silicon, silicon germanium, a Group III-V compound such as GaAs, and any combination of these.

The size, thickness, shape, and layer structure of the substrate are not particularly limited, and can be appropriately selected as desired.

The insulating film in the object to be treated is not particularly limited, and examples thereof include an insulating film containing one or more materials selected from the group consisting of silicon nitride (SiN), silicon oxide, silicon carbide (SiC), silicon carbonitride, silicon oxycarbide (SiOC), silicon oxynitride, and tetraethoxysilane (TEOS). Among these, silicon nitride (SiN), TEOS, silicon carbide (SiC), or silicon oxycarbide (SiOC) is preferable. Furthermore, the insulating film may be composed of a plurality of films.

The barrier layer in the object to be treated is not particularly limited, and examples thereof include a barrier layer containing one or more materials selected from the group consisting of Ta, tantalum nitride (TaN), Ti, titanium nitride (TiN), titanium tungsten (TiW), W, and tungsten nitride (WN). Among these, Ta, TaN, Ti, or TiN is preferable.

The object to be treated may have various layers and/or structures as desired, in addition to the above members. For example, in the case where the object to be treated is a substrate, the object to be treated may have members such as a metal wire, a gate electrode, a source electrode, a drain electrode, an insulating layer, a ferromagnetic layer, and/or a non-magnetic layer.

The object to be treated may have the structure of an exposed integrated circuit, for example, an interconnection mechanism such as a metal wire and a dielectric material. Examples of metals and alloys used for the interconnection mechanism include aluminum, a copper-aluminum alloy, copper, titanium, tantalum, cobalt, silicon, titanium nitride, tantalum nitride, and tungsten. The substrate may have a layer of silicon oxide, silicon nitride, silicon carbide, and/or carbon-doped silicon oxide.

The method for manufacturing the object to be treated is not particularly limited. For example, a method of forming an insulating film on a substrate, forming hole portions (or groove portions) in the insulating film, forming a barrier layer and a metal layer in this order on the insulating film, and then performing a flattening treatment such as chemical mechanical polishing (CMP) makes it possible to form the object 10 to be treated shown in FIG. 1 that has the insulating film 14, the barrier layer 16, and the metal layer 18 on the substrate 12.

The method for forming the barrier layer and the metal layer on the insulating film is not particularly limited, and examples thereof include a sputtering method, a physical vapor deposition (PVD) method, an atomic layer deposition (ALD) method, a chemical vapor deposition (CVD) method, and a molecular beam epitaxy (MBE) method.

Furthermore, the above methods may be performed through a predetermined mask so that a patterned metal layer is formed on a substrate.

### Step A

The present treatment method has a step A of performing an oxidation treatment on an object to be treated having a metal layer so as to form a metal oxide layer.

The object to be treated and the metal layer to which the step A is applied are as described above.

The oxidation treatment performed on the object to be treated having a metal layer is not particularly limited as long as the treatment can form a metal oxide layer. Examples thereof include a treatment of bringing an oxidant into contact with the object to be treated and a treatment of heating the object to be treated.

Examples of the treatment of bringing an oxidant into contact with the object to be treated include a liquid oxidation treatment of bringing an oxidizing liquid into contact with the object to be treated, a gas oxidation treatment of bringing an oxidizing gas into contact with the object to be treated (such as an ozone treatment of bringing an ozone gas into contact with the object to be treated which will be described later or a heating treatment in oxygen that is a treatment of heating the object to be treated in an oxygen atmosphere), and a plasma treatment using an oxygen gas (a dry etching treatment and a plasma ashing treatment).

The oxidant to be brought into contact with a metal-containing substance in the above treatment is not particularly limited. As the oxidant, a substance having a function of oxidizing the metal-containing substance can be selected depending on the type of oxidation treatment. Examples of the oxidant include an oxidizing liquid, an oxidizing gas such as an oxygen-containing gas, and an oxygen gas plasma.

Only one kind of oxidation treatment may be performed, or two or more kinds of oxidation treatments may be performed.

As the oxidation treatment, a liquid oxidation treatment of bringing an oxidizing liquid into contact with the object to be treated is preferable.

The oxidizing liquid is not particularly limited as long as it is a chemical liquid containing a compound having a function of oxidizing the metal layer.

The aforementioned compound is not particularly limited, and includes water, hydrogen peroxide (H₂O₂), FeCl₃, FeF₃, Fe(NO₃)₃, Sr(NO₃)₂, CoF₃, MnF₃, Oxone (2KHSO₅.KHSO₄.K₂SO₄), periodic acid, iodic acid, vanadium (V) oxide, vanadium (IV, V) oxide, ammonium vanadate, an ammonium polyatomic salt {for example, ammonium peroxomonosulfate, ammonium chlorite (NH₄ClO₂), ammonium chlorate (NH₄ClO₃), ammonium iodate (NH₄IO₃), ammonium nitrate (NH₄NO₃), ammonium perborate (NH₄BO₃), ammonium perchlorate (NH₄ClO₄), ammonium periodate (NH₄IO₄), ammonium persulfate ((NH₄)₂S₂O₈), ammonium hypochlorite (NH₄ClO), or ammonium tungstate ((NH₄)₁₀H₂ (W₂O₇))}, a sodium polyatomic salt {for example, sodium persulfate (Na₂S₂O₈), sodium hypochlorite (NaClO), or sodium perborate}, a potassium polyatomic salt {for example, potassium iodate (KlO₃), potassium permanganate (KMnO₄), potassium nitrate (KNO₃), potassium persulfate (K₂S₂O₈), or potassium hypochlorite (KClO)}, a tetramethylammonium polyatomic salt {For example, tetramethylammonium chlorite ((N(CH₃)₄)ClO₂), tetramethylammonium chlorate ((N(CH₃)₄)ClO₃), tetramethylammonium iodate ((N(CH₃)₄)IO₃), tetramethylammonium perborate ((N(CH₃)₄)BO₃), tetramethylammonium perchlorate ((N(CH₃)₄)ClO₄), tetramethylammonium periodate ((N(CH₃)₄)IO₄), or tetramethylammonium persulfate ((N(CH₃)₄)S₂O₈)}, a tetrabutylammonium polyatomic salt {for example, tetrabutylammonium peroxomonosulfate}, peroxomonosulfate, iron nitrate (Fe(NO₃)₃), urea hydrogen peroxide ((CO(NH₂)₂)H₂O₂), peracetic acid (CH₃(CO)OOH), 1,4-benzoquinone, toluquinone, dimethyl-1,4-benzoquinone, chloranil, alloxan, N-methylmorpholine N-oxide, trimethylamine N-oxide, and a combination of these.

In a case where above compound is a salt, a hydrate and/or an anhydride of the salt can also be used.

The oxidizing liquid may contain additives such as an acid and an alkali in addition to the above compound.

The aforementioned oxidizing liquid is preferably at least one chemical liquid selected from the group consisting of water, hydrogen peroxide water, a mixed aqueous solution of ammonia and hydrogen peroxide (APM or SC-1), a mixed aqueous solution of hydrofluoric acid and hydrogen peroxide water (FPM), a mixed aqueous solution of sulfuric acid and hydrogen peroxide water (SPM), a mixed aqueous solution of hydrochloric acid and hydrogen peroxide water (HPM), water containing dissolved oxygen, water containing dissolved ozone, perchloric acid, and nitric acid, and more preferably hydrogen peroxide water or APM.

The hydrogen peroxide water has a composition in which, for example, the content of H₂O₂ is 0.5% to 31% by mass with respect to the total mass of the hydrogen peroxide water. The content of H₂O₂ is more preferably 3% to 15% by mass.

The composition of APM is, for example, preferably in a range of “aqueous ammonia:hydrogen peroxide water:water=1:1:1” to “aqueous ammonia:hydrogen peroxide water:water=1:3:45” (mass ratio).

The composition of FPM is, for example, preferably in a range of “hydrofluoric acid:hydrogen peroxide water:water=1:1:1” to “hydrofluoric acid:hydrogen peroxide water:water=1:1:200” (mass ratio).

The composition of SPM is, for example, preferably in a range of “sulfuric acid:hydrogen peroxide water:water=3:1:0” to “sulfuric acid:hydrogen peroxide water:water=1:1:10” (mass ratio).

The composition of HPM is, for example, preferably in a range of “hydrochloric acid:hydrogen peroxide water:water=1:1:1” to “hydrochloric acid:hydrogen peroxide water:water=1:1:30” (mass ratio).

The preferred compositional ratio described above means a compositional ratio determined in a case where the content of aqueous ammonia is 28% by mass, the content of hydrofluoric acid is 49% by mass, the content of sulfuric acid is 98% by mass, the content of hydrochloric acid is 37% by mass, and the content of hydrogen peroxide water is 30% by mass.

In addition, “A:B:C=x: y: z to A:B:C X: Y: Z” used above to describe a suitable range means that it is preferable that at least one (preferably two and more preferably all) of “A:B=x:y to A:B=X:Y”, “B:C=y:z to B:C=Y:Z”, or “A:C=x:z to A:C=X:Z” be satisfied.

The water containing dissolved oxygen is an aqueous solution having a composition in which, for example, the content of O₂ is 20 to 500 ppm by mass with respect to the total mass of the water containing dissolved oxygen.

The water containing dissolved ozone is an aqueous solution having a composition in which, for example, the content of O₃ is 1 to 60 ppm by mass with respect to the total mass of the water containing dissolved ozone.

Perchloric acid is, for example, an aqueous solution in which the content of HClO₄ is 0.001% to 60% by mass with respect to the total mass of the solution.

Nitric acid is, for example, an aqueous solution in which the content of HNO₃ is 0.001% to 60% by mass with respect to the total mass of the solution.

In the liquid treatment, the method of bringing the object to be treated into contact with the oxidizing liquid is not particularly limited. Examples of the method include a method of immersing the object to be treated in the oxidizing liquid stored in a tank, a method of spraying the oxidizing liquid onto the object to be treated, a method of irrigating the object to be treated with the oxidizing liquid, and any combination of the above methods.

In order to further enhance the oxidation capacity of the oxidizing liquid, a mechanical stirring method may also be used.

Examples of the mechanical stirring method include a method of circulating the oxidizing liquid on an object to be treated, a method of causing the oxidizing liquid to flow on the object to be treated or spraying the oxidizing liquid onto the object to be treated, and a method of stirring the oxidizing liquid by using ultrasonic or megasonic waves.

The contact time between the object to be treated and the oxidizing liquid can be adjusted as appropriate.

The contact time between the object to be treated and the oxidizing liquid is, for example, preferably 10 seconds to 10 minutes, and more preferably 20 seconds to 5 minutes.

The temperature of the oxidizing liquid is preferably 20° C. to 75° C., and more preferably 20° C. to 60° C.

Examples of the oxidizing gas to be brought into contact with the object to be treated in the gas oxidation treatment include dry air, an oxygen gas, an ozone gas, and a mixed gas of these. The oxidizing gas may contain a gas other than these gases.

The oxidizing gas to be brought into contact with the object to be treated in the gas oxidation treatment is preferably an oxygen gas or an ozone gas. In a case where an oxygen gas or an ozone gas is brought into contact with the object to be treated, it is also preferable that the contact be made in an oxygen atmosphere, an ozone atmosphere, or an atmosphere of a mixed gas of oxygen and ozone.

In the gas oxidation treatment, an aspect is also preferable in which the object to be treated (for example, heat the object to be treated at 40° C. to 200° C.) is heated while bringing brought into contact with an oxidizing gas.

The gas oxidation treatment is particularly preferably an ozone treatment of bringing an ozone gas into contact with the object to be treated or a heating treatment in oxygen in which the object to be treated is heated in an oxygen atmosphere.

In the ozone treatment, an ozone gas may be brought into contact with the object to be treated in an ozone atmosphere, or an ozone gas may be brought into contact with the object to be treated in an atmosphere of a mixed gas of an ozone gas and another gas (for example, an oxygen gas). Furthermore, the ozone treatment may be a treatment of heating the object to be treated while bringing the object to be treated into contact with an ozone gas.

The object to be treated applied to the aforementioned oxidation treatment (particularly, the liquid oxidation treatment) may additionally have another layer different from the metal layer oxidized by the oxidation treatment, and a part or all of this another layer may be intentionally or inevitably removed by the oxidation treatment (particularly, the liquid oxidation treatment).

Furthermore, in the oxidation treatment (particularly, the liquid oxidation treatment) described above, a part of the metal-containing substance of the object to be treated may be intentionally or inevitably removed.

In the oxidation treatment, only a part of the surface layer of the metal layer may be oxidized, or the entire surface layer of the metal layer may be oxidized. That is, the metal oxide layer formed by the oxidation treatment may be a layer that is formed by the oxidation of only a part of the surface layer of the metal layer or a layer that is formed by the oxidation of the entire surface layer of the metal layer.

The metal oxide layer formed by the oxidation treatment is preferably a layer consisting of a cobalt oxide, an oxide of a cobalt alloy, a ruthenium oxide, an oxide of a ruthenium alloy, a tungsten oxide, an oxide of a tungsten alloy, a molybdenum oxide, an oxide of a molybdenum alloy, an aluminum oxide, an oxide of an aluminum alloy, a copper oxide, or an oxide of a copper alloy, more preferably a layer consisting of a cobalt oxide or an oxide of a cobalt alloy, and even more preferably a layer consisting of a cobalt oxide.

The thickness of the metal oxide layer formed by the oxidation treatment is not particularly limited, and is, for example, equivalent to the thickness of 1 to 10 atomic layers. The thickness of one atomic layer of a metal is 1 nm or less (for example, 0.3 nm to 0.4 nm).

It is known that in a case where the oxidation treatment is performed using an oxidizing liquid, a phenomenon (self-limit oxidation) occurs in which the thickness of the formed metal oxide layer does not increase even though the oxidation treatment time is increased. The oxidation treatment using an oxidizing liquid is preferable because this treatment makes it possible to easily control the thickness of the metal layer, which is removed by the present treatment method, at the level of several nanometers by the aforementioned phenomenon, unlike a treatment such as a heating treatment in oxygen.

### Step B

The present treatment method includes a step B of bringing the present treatment liquid into contact with the object to be treated having the metal oxide layer obtained by the step A so as to dissolve and remove the metal oxide layer.

The present treatment liquid (treatment liquid for the object to be treated) used in the step B is as described above.

The present treatment liquid exhibits a high dissolving ability for the metal oxide layer formed by the step A but exhibits an extremely low dissolving ability for the metal layer present as an underlayer of the metal oxide layer. Therefore, the present treatment liquid has excellent etching selectivity which means that the present treatment liquid is well able to remove the metal oxide layer by etching but further suppresses the removal of the metal layer that is exposed after the metal oxide layer is removed.

Accordingly, the present treatment method using the present treatment liquid makes it possible to remove (dissolve) only the extremely thin surface layer (metal oxide layer) formed by the step A and to further suppress the dissolution of the metal layer exposed after the metal oxide layer is removed. Therefore, for example, even in a case where a variation occurs in the contact time between the exposed metal layer and the present treatment liquid, such as a case where the rate of removal of the metal oxide layer by the step B varies with the position in the in-plane direction of the object to be treated, it is possible to inhibit the etching amount of the metal layer from varying in the in-plane direction and to improve flatness of the metal layer formed by the present treatment method.

There is no particular limitation on the method of the step B of bringing the present treatment liquid into contact with the object to be treated so as to dissolve and remove the metal oxide layer. Examples of the method include a method of immersing the object to be treated in the treatment liquid stored in a tank, a method of spraying the treatment liquid onto the object to be treated, a method of causing the treatment liquid to flow on the object to be treated, and any combination of these.

In order to further enhance the removing ability of the treatment liquid, a mechanical stirring method may also be used.

Examples of the mechanical stirring method include a method of circulating the treatment liquid on an object to be treated, a method of causing the treatment liquid to flow on the object to be treated or spraying the treatment liquid onto the object to be treated, and a method of stirring the treatment liquid by using ultrasonic or megasonic waves.

The contact time between the object to be treated and the treatment liquid can be adjusted as appropriate.

The contact time between the object to be treated and the treatment liquid is preferably 10 seconds to 10 minutes, and more preferably 20 seconds to 5 minutes.

The temperature of the treatment liquid is preferably 20° C. to 75° C., and more preferably 20° C. to 60° C.

In the step B, the metal oxide layer may be partially or totally removed.

It is preferable that the dissolved oxygen content in the present treatment liquid used in the step B be low. Specifically, the dissolved oxygen concentration in the treatment liquid is preferably 200 ppb by mass or less, and more preferably 70 ppb by mass or less.

In a case where the treatment liquid contains a large amount of dissolved oxygen, the metal layer exposed as a result of removal of the metal oxide layer by the treatment liquid is oxidized by the dissolved oxygen in the treatment liquid and turns into a new metal oxide layer, and this metal oxide layer is also removed by the treatment liquid, which sometimes leads to the removal of an excess of metal layer. In contrast, using a treatment liquid with a low dissolved oxygen content makes it possible to suppress the change in the etching amount of the metal layer and to further improve the effect of the present invention.

The treatment liquid with a low dissolved oxygen content can be manufactured, for example, by performing a deaerating treatment on the treatment liquid in advance by using an inert gas such as nitrogen.

### Rinsing Step

As necessary, the present treatment method may have a rinsing step of performing a rinsing treatment on the object to be treated by using a rinsing liquid.

It is preferable that the present treatment method have a first rinsing step which is performed between the step A and the step B, as a step of supplying a rinsing liquid to the surface of the object to be treated obtained by the step A so as to wash away the oxidant (preferably the oxidizing liquid) attached to the surface of the object to be treated.

Performing the first rinsing step on the object to be treated obtained by the step A makes it possible to inhibit the surface of the metal layer to be exposed in the subsequent step B from being oxidized and removed by the oxidant remaining on the surface of the object to be treated. Accordingly, performing the first rinsing step makes it possible to suppress the change in the total etching amount and to further improve the effect of the present invention.

Furthermore, it is preferable that the present treatment method have a second rinsing step which is performed after the step B, as a step of supplying a rinsing liquid to the surface of the object to be treated obtained by the step B so as to wash away the present treatment liquid attached to the surface of the object to be treated.

In a case where the second rinsing step is performed on the object to be treated obtained by the step B, oxygen in the atmosphere is likely to be dissolved in the treatment liquid remaining on the surface of the object to be treated, and the surface of the newly exposed metal layer is likely to be oxidized due to the dissolved oxygen. In this case, for example, a variation is likely to occur in the thickness of the metal oxide layer formed by the repeated step A, which is likely to lead to the change in the total etching amount by the treatment method. In contrast, in a case where the second rinsing step is performed to inhibit the present treatment liquid from being attached to the surface of the object to be treated, it is possible to suppress the change in the total etching amount and to further improve the effect of the present invention.

Hereinafter, the rinsing liquid used in the rinsing step including the first rinsing step and the second rinsing step, and the specific method of the rinsing treatment will be described.

Hereinafter, in a case where the term “rinsing step”, “rinsing treatment”, or “rinsing liquid” is simply described in the present specification, unless otherwise specified, the descriptions relating to the terms are the matters common to both the first rinsing step and second rinsing step.

As the rinsing liquid, for example, water, hydrofluoric acid (preferably 0.001% to 1% by mass hydrofluoric acid), hydrochloric acid (preferably 0.001% to 1% by mass hydrochloric acid), hydrogen peroxide water (preferably 0.5% to 31% by mass hydrogen peroxide water, and more preferably 3% to 15% by mass hydrogen peroxide water), a mixed solution of hydrofluoric acid and hydrogen peroxide water (FPM), a mixed solution of sulfuric acid and hydrogen peroxide water (SPM), a mixed solution of aqueous ammonia and hydrogen peroxide water (APM), a mixed solution of hydrochloric acid and hydrogen peroxide water (HPM), aqueous carbon dioxide (preferably 10 to 60 ppm by mass aqueous carbon dioxide), aqueous ozone (preferably 10 to 60 ppm by mass aqueous ozone), aqueous hydrogen (preferably 10 to 20 ppm by mass aqueous hydrogen), an aqueous citric acid solution (preferably a 0.01% to 10% by mass aqueous citric acid solution), sulfuric acid (preferably a 1% to 10% by mass aqueous sulfuric acid solution), aqueous ammonia (preferably 0.01% to 10% by mass aqueous ammonia), isopropyl alcohol (IPA), an aqueous hypochlorous acid solution (preferably a 1% to 10% by mass aqueous hypochlorous acid solution), aqua regia (preferably aqua regia obtained by mixing together “37% by mass hydrochloric acid:60% by mass nitric acid” at a volume ratio of “2.6:1.4” to “3.4:0.6”), ultrapure water, nitric acid (preferably 0.001% to 1% by mass nitric acid), perchloric acid (preferably 0.001% to 1% by mass perchloric acid), an aqueous oxalic acid solution (preferably a 0.01% to 10% by mass aqueous oxalic acid solution), acetic acid (preferably a 0.01% to 10% by mass aqueous acetic acid solution or an undiluted acetic acid solution), or an aqueous periodic acid solution (preferably a 0.5% to 10% by mass aqueous periodic acid solution. As the periodic acid, for example, orthoperiodic acid and metaperiodic acid are preferable, and isopropyl alcohol (IPA) is more preferable.

The preferred conditions required to FPM, SPM, APM, and HPM are the same as the preferred conditions required, for example, to FPM, SPM, APM, and HPM used as the aforementioned oxidizing liquid.

The hydrofluoric acid, nitric acid, perchloric acid, and hydrochloric acid mean aqueous solutions obtained by dissolving HF, HNO₃, HClO₄, and HCl in water respectively.

The aqueous ozone, aqueous carbon dioxide, and aqueous hydrogen mean aqueous solutions obtained by dissolving O₃, CO₂, and H₂ in water respectively.

As long as the purpose of the rinsing step is not impaired, these rinsing liquids may be used by being mixed together. The rinsing liquid may also contain an organic solvent.

It is preferable that the dissolved oxygen content in the rinsing liquid used in the rinsing step be low. Specifically, the dissolved oxygen concentration in the rinsing liquid is preferably 200 ppb by mass or less, and more preferably 70 ppb by mass or less.

Using a rinsing liquid with a low dissolved oxygen content just as the present treatment liquid makes it possible to suppress the change in the etching amount of the metal layer and to further improve the effect of the present invention.

The rinsing liquid with a low dissolved oxygen content can be manufactured, for example, by performing a deaerating treatment on the rinsing liquid in advance by using an inert gas such as nitrogen.

Examples of the specific method of the rinsing step include a method of bringing the rinsing liquid into contact with the object to be treated.

The method of bringing the rinsing liquid into contact with the object to be treated is performed by a method of immersing the substrate in the rinsing liquid stored in a tank, a method of spraying the rinsing liquid onto the substrate, a method of causing the rinsing liquid to flow on the substrate, or a combined method consisting of any of the above methods.

The treatment time (contact time between the rinsing liquid and the object to be treated) is not particularly limited, but is 5 seconds to 5 minutes for example.

The temperature of the rinsing liquid during the treatment is not particularly limited, but is preferably 15° C. to 60° C. and more preferably 20° C. to 40° C. In a case where SPM is used as the rinsing liquid, the temperature thereof is preferably 90° C. to 250° C.

### Drying Step

As necessary, the present treatment method may have a drying step of performing a drying treatment after the rinsing step. The method of the drying treatment is not particularly limited, and examples thereof include spin drying, causing a drying gas to flow on the substrate, heating the substrate by a heating unit (for example, a hot plate or an infrared lamp), isopropyl alcohol (IPA) vapor drying, Marangoni drying, Rotagoni drying, and any combination of these.

The drying time may be appropriately set according to the rinsing liquid to be used, but is, for example, about 30 seconds to several minutes.

The drying step is preferably performed after the second rinsing step (at least after the last second rinsing step in a case where the second rinsing step is performed a plurality of times).

### Cycle Etching

In the present treatment method, it is preferable to repeat the step A and the step B. In the present treatment method, in a case where at least one step selected from the first rinsing step, the second rinsing step, and the drying step is performed as necessary, it is preferable that each of these steps be repeated.

Repeating the step A and the step B in this way makes it possible to control the total etching amount of the metal layer removed by the present treatment method with high accuracy.

In a case where the step A and the step B are alternately repeated, the number of times (number of cycles) of each of the step A and the step B performed is preferably 1 to 20, and more preferably 3 to 10.

The present treatment method may have other steps in addition to the above steps.

Examples of those other steps include the coating film forming step described in “0021” of JP2019-061978A and the like and the laser irradiating step described in “0022” of JP2019-061978A and the like. What are described in these paragraphs are incorporated into the present specification.

The present treatment method may be performed in combination with a semiconductor device manufacturing method, before or after the steps performed in the manufacturing method. While being performed, the present treatment method may be incorporated into those other steps. Alternatively, while those other steps are being performed, the present treatment method may be incorporated into the steps and performed.

Examples of those other steps include a step of forming each structure such as a metal wire, a gate structure, a source structure, a drain structure, an insulating layer, a ferromagnetic layer and/or a non-magnetic layer (layer formation, etching, CMP and/or modification, and the like), a step of forming resist, an exposure step and a removing step, a heat treatment step, a washing step, and an inspection step.

The present treatment method may be performed at any stage in the back end process (BEOL: Back end of the line), the middle process (MOL: Middle of the line), or in the front end process (FEOL: Front end of the line). It is preferable that the present treatment method be performed in BEOL or MOL.

The application target of the present treatment method may be, for example, NAND, Dynamic Random Access Memory (DRAM), Static Random Access Memory (SRAM), Resistive Random Access Memory (ReRAM), Ferroelectric Random Access Memory (FRAM (registered trademark)), Magnetoresistive Random Access Memory (MRAM), or Phase change Random Access Memory (PRAM), or may be a logic circuit or a processor.

### Example

Hereinafter, the present invention will be more specifically described based on examples. The materials, the amounts and ratios of the materials used, the details of treatments, the procedures of treatments, and the like shown in the following examples can be appropriately changed as long as the gist of the present invention is maintained. Therefore, the scope of the present invention is not limited to the following examples.

In the examples, unless otherwise specified, “%” means “% by mass”, and “ppb” means “ppb by mass”.

### Preparation of Treatment Liquid

The following components were mixed together in a predetermined formulation, thereby preparing treatment liquids to be used in each test.

Each of raw materials used in each of the following treatment liquids was a high-purity grade material, which was further purified in advance by distillation, ion exchange, filtration, or a combination of these.

### Organic Solvent

Diethylene glycol diethyl ether (DEGDEE) (ether-based solvent)

Propylene glycol diacetate (PGDA) (ester-based solvent)

Ethylene glycol monobutyl ether (EGBE) (alcohol-based solvent)

Propylene glycol (alcohol-based solvent)

Tetraethylene glycol dimethyl ether (tetraglyme) (ether-based solvent)

Benzyl alcohol (alcohol-based solvent)

Propylene carbonate (ester-based solvent)

Diethylene glycol monobutyl ether (DEGBE) (alcohol-based solvent)

Methyl ethyl ketone (ketone-based solvent)

3-Methoxy-3-methyl-1-butanol (MMB) (alcohol-based solvent)

Propylene glycol monomethyl ether acetate (PGMEA) (ester-based solvent)

### Acidic Compound

Acetic acid

Oxalic acid

Malonic acid

Citric acid

Benzoic acid

Methanesulfonic acid

Malic acid

Tartaric acid

Hydrofluoric acid

### Optional Components

Urea

Thiourea

Hydroquinone

1,2,3-Triazole

### Water

Water: water obtained by repeating a purification treatment consisting of distillation, filtration, and ion exchange on ultrapure water was used.

As a result of preparing treatment liquids by using waters subjected to the purification treatment under different conditions and/or waters subjected to the purification treatment different number of times, treatment liquids having the total content of Ni and Cu shown in Table 1 were obtained.

### Metal Content

The content of Ni and Cu contained in the treatment liquid of each of the examples and comparative examples was measured using Agilent 8800 triple quadrupole inductively coupled plasma mass spectrometry (ICP-MS, for semiconductor analysis, option #200).

### Measurement Conditions

As a sample introduction system, a quartz torch, a coaxial perfluoroalkoxyalkane (PFA) nebulizer (for self-suction), and a platinum interface cone were used. The measurement parameters of cool plasma conditions are as follows.
Radio frequency (RF) output (W): 600
Flow rate of carrier gas (L/min): 0.7
Flow rate of makeup gas (L/min): 1
Sampling depth (mm): 18

In measuring the content of Ni and Cu, the treatment liquid for which the content of Ni and Cu is to be determined was adopted as a measurement target. In a case where the treatment liquid was adopted as a measurement target, and the content of Ni and Cu in the treatment liquid was less than the detection limit, the treatment liquid as a measurement target was measured again after being appropriately concentrated, and the value obtained by the measurement was converted into the concentration of the treatment liquid not yet being concentrated, thereby calculating the content of Ni and Cu.

### Test

The following tests were performed using the prepared treatment liquids of examples or comparative examples.

### Evaluation on Etching Selectivity of Treatment Liquid

Substrates were prepared in which a metallic cobalt (Co) layer was formed on one surface of a commercially available silicon wafer (diameter: 12 inches) by a CVD method. The thickness of the Co layer was 40 nm.

Each of the obtained substrates was put in a container filled with the treatment liquid of each of the examples and comparative examples, and the treatment liquid was stirred for 15 minutes as a Co layer removal treatment. The temperature of the treatment liquid was 30° C.

Before and after the above removal treatment, the thickness of the Co layer on each substrate was measured. The thickness of the Co layer was measured using an X-ray fluorescence spectrometer (“AZX400” manufactured by Rigaku Corporation). From the difference in thickness between the Co layer before the removal treatment and the Co layer after the removal treatment, an etching rate (Å/min) of the Co layer was calculated. From the calculated etching rate of the Co layer, the etching selectivity of each treatment liquid was evaluated based on the following standard. The lower the etching rate of the Co layer, the better the etching selectivity of the treatment liquid.

### Evaluation Standard for Etching Selectivity

A: The etching rate is more than 25 Å/min.

B: The etching rate is more than 10 Å/min and 25 Å/min or less.

C: The etching rate is 2 Å/min or more and 10 Å/min or less.

D: The etching rate is 0.5 Å/min or more and 2 Å/min or less.

E: The etching rate is less than 0.5 Å/min.

Table 1 which will be described later shows the composition of the treatment liquid of each of the examples and comparative examples prepared by the above method, the etching rate of the Co layer measured for the treatment liquid of each of the examples and comparative examples, and the results of evaluation on etching selectivity.

In Table 1, “Amount (%)” means the content (unit: % by mass) of each component with respect to the total mass of the treatment liquid, and “ppb” means the content (unit: ppb by mass) of each component with respect to the total mass of the treatment liquid.

### Treatment Test

### Preparation of Object to be Treated

An object to be treated was prepared which has a substrate, an insulating film (SiO₂ film) disposed on the substrate and having grooves, a barrier layer (TiN layer) disposed along the inner wall of each of the grooves, and a Co-containing wiring line with which the grooves are filled.

This object to be treated was manufactured by a method including a step of forming an insulating film on a substrate, a step of forming grooves in the insulating film, a step of forming a barrier layer on the insulating film, a step of forming a Co-containing film so that the grooves are filled, and a step of performing a CMP treatment as a flattening treatment on the Co-containing film and the barrier layer until the insulating film is exposed.

### Treating Object to be Treated

### Step A

The oxidizing liquids used in the treatment (step A) for the object to be treated are as below. Each of the oxidizing liquids used was a high-purity grade oxidizing liquid, which was purified in advance by distillation, ion exchange, filtration, or a combination of these.
H₂O₂: 1% by mass aqueous hydrogen peroxide solution
DIW: deionized water
SC-1 (1): mixed solution of 28% by mass aqueous ammonia:30% by mass hydrogen peroxide water:water=1:1:30 (volume ratio)
SC-1 (2): mixed solution of 28% by mass aqueous ammonia:30% by mass hydrogen peroxide water:water=1:2:30 (volume ratio)

Each of the oxidizing liquids was supplied to the surface of the obtained object to be treated for a predetermined time, thereby forming a cobalt oxide layer on the surface of the Co-containing wiring line of the object to be treated. Table 2 shows the oxidizing liquid used in each of the examples and comparative examples, the temperature of the oxidizing liquid, and the time for which the oxidizing liquid was supplied.

### First Rinsing Step

As the first rinsing step, a rinsing treatment was performed in which a rinsing liquid was supplied to the surface of the object to be treated having undergone the step A for a predetermined time. Table 2 shows the conditions of the first rinsing step in each of the examples and comparative examples.

For example, in Example 1, the surface of the object to be treated having undergone the step A was rinsed with deionized water for 15 seconds and then rinsed with isopropanol (IPA) for 15 seconds.

### Step B

As the step B, a treatment was performed in which the treatment liquid of each of the examples and comparative examples prepared by the above method was supplied for a predetermined time to the surface of the object to be treated having undergone the first rinsing step so that the cobalt oxide layer formed by the step A was removed. Table 2 shows the temperature of each treatment liquid used in the step B and the time for which the treatment liquid was supplied.

### Second Rinsing Step

As the second rinsing step, a rinsing treatment was performed in which a rinsing liquid was supplied for a predetermined time to the surface of the object to be treated having undergone the step B. Table 2 shows the conditions of the second rinsing step in each of the examples and comparative examples. For example, in Example 1, the surface of the object to be treated having undergone the step B was rinsed with isopropanol (WA) for 30 seconds.

The step A, the first rinsing step, the step B, and the second rinsing step were repeated a predetermined number of times, thereby obtaining an object to be treated from which the surface layer of the Co-containing wiring line was removed. Table 2 shows the number of times (number of cycles) the step A, the first rinsing step, the step B, and the second rinsing step were repeated in each of the examples and comparative examples.

### Evaluation on Treatment Method

### Evaluation on Etching Amount

The thickness of the Co-containing wiring line was measured before and after the object to be treated was subjected to the above treatment. From the difference between the thickness before the treatment and the thickness after the treatment, a removal amount (etching amount, unit: nm) of the Co-containing wiring line removed by the above treatment was calculated.

### Evaluation on Flatness

Furthermore, in the object to be treated having undergone the treatment, the Co-containing wiring line at a random position was selected, and the difference (unit: nm) between the maximum etching amount and the minimum etching amount measured in a section having a length of 1 mm where the Co-containing wiring line extends was calculated. The difference was calculated for the Co-containing wiring line at random three sites, and the average thereof was calculated (hereinafter, the average will be also described as “difference in etching amount”). From the obtained difference in etching amount, the flatness of the surface of the Co-containing film removed by the treatment method of each of the examples and comparative examples was evaluated based on the following standard.

### Evaluation Standard for Flatness

A: The difference in etching amount is 5 nm or less.

B: The difference in etching amount is more than 5 nm and 10 nm or less.

C: The difference in etching amount is more than 10 nm and 20 nm or less.

D: The difference in etching amount is more than 20 nm.

### Evaluation on Anti-Pitting Properties

In the object to be treated having undergone the treatment, the surface of the Co-containing wiring line exposed by the above treatment was observed with a scanning electron microscope (SEM) so as to check whether or not a hole-shaped defect is on the wiring line surface.

In a case where a hole-shaped defect was found on the wiring line surface in the observed image, “Occur” was written in Table 2. In a case where such a defect was not found, “Not occur” was written in Table 2. It is preferable that no hole-shaped defect be found on the wiring line surface.

### Result

Table 2 shows each step and the number of cycles of the above treatment method and the results of evaluation on the treatment method.

TABLE 1

| | | | | | | | | | Treatment liquid | |
|---|---|---|---|---|---|---|---|---|---|---|
| | | | | | | | | | Evaluation | |
| | | | | | | | | | Co ER | |
| | Treatment liquid Composition | | | | | | | | Measured | |
| | Organic solvent | | Acidic compound | | Optional component | | Water | | etching | |
| | | Amount | | Amount | | Amount | Amount | Ni + Cu | rate | |
| Table 1 | Compound | (%) | Compound | (%) | Compound | (%) | (%) | (ppb) | (Å/min) | Evaluation |
| Example 1 | DEGDEE | 95.00 | Acetic acid | 5.00 | | | | 1.0 | 5.2 | C |
| Example 2 | PGDA | 96.00 | Oxalic acid | 4.00 | | | | 2.0 | 0.3 | A |
| Example 3 | DEGDEE | 95.00 | Malonic acid | 5.00 | | | | 2.5 | 0.1 | A |
| Example 4 | DEGDEE | 95.70 | Citric acid | 4.00 | | | 0.30 | 0.5 | 0.1 | A |
| Example 5 | DEGDEE | 97.00 | Benzoic acid | 3.00 | | | | 1.5 | 0.1 | A |
| Example 6 | DEGDEE | 96.00 | Citric acid | 4.00 | | | | 0.2 | 0.6 | B |
| Example 7 | EGBE | 97.00 | Methanesulfonic | 3.00 | | | | 0.5 | 1.5 | B |
| | | | acid | | | | | | | |
| Example 8 | Propylene | 90.00 | Acetic acid | 10.00 | | | | 0.2 | 3.4 | C |
| | glycol | | | | | | | | | |
| Example 9 | Tetraglyme | 65.00 | Acetic acid | 35.00 | | | | 1.0 | 4.5 | C |
| Example 10 | DEGDEE | 95.95 | Citric acid | 4.00 | Urea | 0.05 | | 0.5 | 0.2 | A |
| Example 11 | DEGDEE | 94.90 | Malonic acid | 5.00 | Thiourea | 0.10 | | 0.8 | 0.1 | A |
| Example 12 | DEGDEE | 94.00 | Acetic acid | 1.00 | | | 5.00 | 1.3 | 8.0 | C |
| Example 13 | DEGDEE | 79.00 | Acetic acid | 1.00 | | | 20.00 | 4.0 | 10.0 | C |
| Example 14 | Tetraglyme | 86.00 | Benzoic acid | 5.00 | | | 9.00 | 3.1 | 9.0 | C |
| Example 15 | Benzyl alcohol | 95.00 | Benzoic acid | 5.00 | | | | 2.1 | 0.6 | B |
| Example 16 | Benzyl alcohol | 95.00 | Benzoic acid | 5.00 | | | | 9.0 | 0.6 | B |
| Example 17 | Benzyl alcohol | 95.00 | Benzoic acid | 5.00 | | | | 15.0 | 0.6 | B |
| Example 18 | Propylene | 97.50 | Malonic acid | 2.50 | | | | 0.5 | 0.2 | A |
| | carbonate | | | | | | | | | |
| Example 19 | DEGDEE | 95.90 | Citric acid | 4.00 | Hydroquinone | 0.10 | | 0.3 | 0.1 | A |
| Example 20 | DEGBE | 74.00 | Oxalic acid | 6.00 | | | | 0.8 | 0.2 | A |
| | DEGDEE | 20.00 | | | | | | | | |
| Example 21 | DEGBE | 97.50 | Malic acid | 2.50 | | | | 1.2 | 0.1 | A |
| Example 22 | Propylene | 85.00 | Malonic acid | 5.00 | | | | 0.9 | 0.2 | A |
| | carbonate | 10.00 | | | | | | | | |
| | DEGDEE | | | | | | | | | |
| Example 23 | Propylene | 95.00 | Malonic acid | 5.00 | | | | 0.1 | 0.1 | A |
| | carbonate | | | | | | | | | |
| Example 24 | Propylene | 90.00 | Malonic acid | 10.00 | | | | 0.9 | 0.2 | A |
| | carbonate | | | | | | | | | |
| Example 25 | Methyl ethyl | 90.00 | Oxalic acid | 10.00 | | | | 1.1 | 1.8 | B |
| | ketone | | | | | | | | | |

TABLE 2

| | | | | | | | | | Treatment liquid | |
|---|---|---|---|---|---|---|---|---|---|---|
| | | | | | | | | | Evaluation | |
| | | | | | | | | | Co ER | |
| | Treatment liquid Composition | | | | | | | | Measured | |
| | Organic solvent | | Acidic compound | | Optional component | | Water | | etching | |
| Table 1 | | Amount | | Amount | | Amount | Amount | Ni + Cu | rate | |
| (continued) | Compound | (%) | Compound | (%) | Compound | (%) | (%) | (ppb) | (Å/min) | Evaluation |
| Example 26 | MMB | 95.00 | Benzoic acid | 5.00 | | | | 1.0 | 1.0 | B |
| Example 27 | PGMEA | 90.00 | Malic acid | 10.00 | | | | 0.5 | 1.2 | B |
| Example 28 | Tetraglyme | 96.00 | Oxalic acid | 4.00 | | | | 0.4 | 0.2 | A |
| Example 29 | Tetraglyme | 70.00 | Citric acid | 30.00 | | | | 0.2 | 9.0 | C |
| Example 30 | DEGDEE | 96.00 | Citric acid | 4.00 | | | | 20.0 | 0.2 | A |
| Example 31 | Tetraglyme | 94.00 | Tartaric acid | 6.00 | | | | 0.8 | 0.1 | A |
| Example 32 | DEGDEE | 94.90 | Malic acid | 5.00 | 1,2,3-Triazole | 0.10 | | 1.1 | 0.1 | A |
| Example 33 | DEGDEE | 94.90 | Malic acid | 5.00 | | | | 0.9 | 0.1 | A |
| | EGBE | 0.10 | | | | | | | | |
| Example 34 | Tetraglyme | 50.00 | Malic acid | 5.00 | | | 45.00 | 0.8 | 9.9 | C |
| Example 35 | DEGDEE | 60.00 | Malonic acid | 5.00 | | | 35.00 | 1.1 | 9.6 | C |
| Example 36 | Tetraglyme | 76.00 | Benzoic acid | 5.00 | | | 19.00 | 3.1 | 9.6 | C |
| Example 37 | Tetraglyme | 67.50 | Acetic acid | 32.50 | | | | 3.1 | 6.5 | C |
| Example 38 | Tetraglyme | 84.00 | Benzoic acid | 5.00 | | | 11.00 | 2.0 | 9.6 | C |
| Example 39 | Tetraglyme | 86.00 | Oxalic acid | 5.00 | | | 9.00 | 1.0 | 8.2 | C |
| Example 40 | Propylene | 90.00 | Oxalic acid | 5.00 | | | 5.00 | 0.5 | 2.0 | B |
| | carbonate | | | | | | | | | |
| Example 41 | Tetraglyme | 94.00 | Acetic acid | 5.00 | | | | 1.0 | 0.5 | A |
| | | | Oxalic acid | 1.00 | | | | | | |
| Comparative | | | Acetic acid | 85.00 | | | 15.00 | 1.1 | 30.2 | E |
| Example 1 | | | | | | | | | | |
| Comparative | | | Hydrofluoric | 1.00 | | | 99.00 | 0.6 | >100 | E |
| Example 2 | | | acid | | | | | | | |
| Comparative | | | Citric acid | 1.00 | | | 99.00 | 0.7 | 50.3 | E |
| Example 3 | | | | | | | | | | |
| Comparative | | | Acetic acid | 100.00 | | | | 1.3 | 18.0 | D |
| Example 4 | | | | | | | | | | |
| Comparative | | | Methanesulfonic | 100.00 | | | | 5.0 | 20.2 | D |
| Example 5 | | | acid | | | | | | | |
| Comparative | Tetraglyme | 47.50 | Citric acid | 1.00 | | | 51.50 | 5.0 | 19.0 | D |
| Example 6 | | | | | | | | | | |

TABLE 3

| | | | | | | | | | Treatment method | | |
|---|---|---|---|---|---|---|---|---|---|---|---|
| | | | | | | | | | Evaluation | | |
| | Treatment method | | | | | | | | | | Whether |
| | Step A | | | | Step B | | Second | Number | Etching | | or not |
| | | Temperature | Time | | Temperature | Time | rinsing | of | amount | | pitting |
| Table 2 | Oxidant | CO | (sec) | First rinsing step | (° C.) | (sec) | step | cycles | (nm) | Flatness | occurs |
| Example | H₂O₂ | 30 | 30 | DIW 15 sec + IPA 15 | 30 | 10 | IPA 30 | 4 | 12.5 | C | Not |
| 1 | | | | sec | | | sec | | | | occur |
| Example | DIW | 40 | 30 | IPA 30 sec | 30 | 30 | IPA 30 | 5 | 13.4 | B | Not |
| 2 | | | | | | | sec | | | | occur |
| Example | DIW | 40 | 30 | IPA 30 sec | 30 | 30 | IPA 30 | 3 | 9.4 | A | Not |
| 3 | | | | | | | sec | | | | occur |
| Example | DIW | 40 | 30 | IPA 30 sec | 30 | 30 | IPA 30 | 4 | 11.2 | A | Not |
| 4 | | | | | | | sec | | | | occur |
| Example | DIW | 40 | 30 | IPA 30 sec | 30 | 30 | IPA 30 | 3 | 9.9 | A | Not |
| 5 | | | | | | | sec | | | | occur |
| Example | DIW | 40 | 30 | IPA 30 sec | 30 | 10 | IPA 30 | 3 | 8.3 | B | Not |
| 6 | | | | | | | sec | | | | occur |
| Example | H₂O₂ | 30 | 30 | DIW 15 sec + IPA 15 | 30 | 30 | IPA 30 | 3 | 9.0 | C | Not |
| 7 | | | | sec | | | sec | | | | occur |
| Example | DIW | 40 | 30 | IPA 30 sec | 30 | 30 | IPA 30 | 3 | 11.1 | B | Not |
| 8 | | | | | | | sec | | | | occur |
| Example | DIW | 40 | 30 | IPA 30 sec | 30 | 10 | IPA 30 | 3 | 10.3 | C | Not |
| 9 | | | | | | | sec | | | | occur |
| Example | DIW | 40 | 30 | IPA 30 sec | 30 | 30 | IPA 30 | 3 | 9.3 | A | Not |
| 10 | | | | | | | sec | | | | occur |
| Example | DIW | 40 | 30 | IPA 30 sec | 30 | 30 | IPA 30 | 3 | 9.7 | A | Not |
| 11 | | | | | | | sec | | | | occur |
| Example | SC-1(2) | 30 | 30 | DIW 15 sec + IPA 15 | 30 | 30 | IPA 30 | 4 | 11.4 | B | Not |
| 12 | | | | sec | | | sec | | | | occur |
| Example | H₂O₂ | 30 | 30 | DIW 15 sec + IPA 15 | 30 | 30 | IPA 30 | 3 | 10.2 | C | Not |
| 13 | | | | sec | | | sec | | | | occur |
| Example | H₂O₂ | 30 | 30 | DIW 15 sec + IPA 15 | 30 | 30 | IPA 30 | 3 | 13.4 | B | Not |
| 14 | | | | sec | | | sec | | | | occur |
| Example | H₂O₂ | 30 | 30 | DIW 15 sec + IPA 15 | 30 | 30 | IPA 30 | 3 | 11.2 | A | Not |
| 15 | | | | sec | | | sec | | | | occur |
| Example | DIW | 40 | 30 | IPA 30 sec | 30 | 30 | IPA 30 | 3 | 10.8 | A | Not |
| 16 | | | | | | | sec | | | | occur |
| Example | SC-1(2) | 30 | 30 | DIW 15 sec + IPA 15 | 30 | 30 | IPA 30 | 4 | 12.2 | A | Occur |
| 17 | | | | sec | | | sec | | | | |
| Example | SC-1(1) | 30 | 30 | DIW 15 sec + IPA 15 | 30 | 30 | IPA 30 | 4 | 12.2 | A | Not |
| 18 | | | | sec | | | sec | | | | occur |
| Example | DIW | 40 | 30 | IPA 30 sec | 30 | 30 | IPA 30 | 4 | 11.8 | A | Not |
| 19 | | | | | | | sec | | | | occur |
| Example | DIW | 40 | 30 | IPA 30 sec | 30 | 30 | IPA 30 | 4 | 11.9 | A | Not |
| 20 | | | | | | | sec | | | | occur |
| Example | H₂O₂ | 30 | 30 | DIW 15 sec + IPA 15 | 30 | 30 | IPA 30 | 4 | 12.9 | A | Not |
| 21 | | | | sec | | | sec | | | | occur |
| Example | SC-1(1) | 30 | 30 | DIW 15 sec + IPA 15 | 30 | 30 | IPA 30 | 4 | 11.3 | A | Not |
| 22 | | | | sec | | | sec | | | | occur |
| Example | DIW | 40 | 30 | IPA 30 sec | 30 | 30 | IPA 30 | 4 | 11.1 | A | Not |
| 23 | | | | | | | sec | | | | occur |
| Example | DIW | 40 | 30 | IPA 30 sec | 30 | 30 | IPA 30 | 4 | 12.5 | A | Not |
| 24 | | | | | | | sec | | | | occur |
| Example | SC-1(2) | 30 | 30 | DIW 15 sec + IPA 15 | 30 | 30 | IPA 30 | 3 | 9.8 | B | Not |
| 25 | | | | sec | | | sec | | | | occur |

TABLE 4

| | | | | | | | | | Treatment method | | |
|---|---|---|---|---|---|---|---|---|---|---|---|
| | | | | | | | | | Evaluation | | |
| | Treatment method | | | | | | | | | | Whether |
| | Step A | | | | Step 13 | | Second | Number | Etching | | or not |
| Table 2 | | Temperature | Time | | Temperature | Time | rinsing | of | amount | | pitting |
| (continued) | Oxidant | (° C.) | (sec) | First rinsing step | (° C.) | (sec) | step | cycles | (nm) | Flatness | occurs |
| Example 26 | DIW | 40 | 30 | IPA 30 sec | 30 | 30 | IPA 30 | 5 | 14.3 | B | Not |
| | | | | | | | see | | | | occur |
| Example 27 | DIW | 40 | 30 | IPA 30 sec | 30 | 30 | IPA 30 | 5 | 14.3 | B | Not |
| | | | | | | | sec | | | | occur |
| Example 28 | SC-1(1) | 30 | 30 | DIW 15 sec + IPA | 30 | 30 | IPA 30 | 4 | 9.1 | A | Not |
| | | | | 15 sec | | | sec | | | | occur |
| Example 29 | DIW | 40 | 30 | IPA 30 sec | 30 | 30 | IPA 30 | 5 | 18.2 | B | Not |
| | | | | | | | sec | | | | occur |
| Example 30 | DIW | 40 | 30 | IPA 30 sec | 30 | 30 | IPA 30 | 5 | 15.2 | A | Occur |
| | | | | | | | sec | | | | |
| Example 31 | H₂O₂ | 30 | 30 | DIW 15 sec + IPA | 30 | 30 | IPA 30 | 3 | 9.4 | A | Not |
| | | | | 15 sec | | | sec | | | | occur |
| Example 32 | SC-1(1) | 30 | 30 | DIW 15 sec + IPA | 30 | 30 | IPA 30 | 5 | 13.2 | A | Not |
| | | | | 15 sec | | | sec | | | | occur |
| Example 33 | DIW | 30 | 30 | IPA 30 sec | 30 | 30 | IPA 30 | 5 | 13.3 | A | Not |
| | | | | | | | sec | | | | occur |
| Example 34 | SC-1(1) | 30 | 30 | DIW 15 sec + IPA | 30 | 30 | IPA 30 | 5 | 17.0 | C | Occur |
| | | | | 15 sec | | | sec | | | | |
| Example 35 | DIW | 30 | 30 | IPA 30 sec | 30 | 30 | IPA 30 | 5 | 18.1 | C | Occur |
| | | | | | | | sec | | | | |
| Example 36 | H₂O₂ | 30 | 30 | DIW 15 sec + IPA | 30 | 30 | IPA 30 | 3 | 13.4 | C | Not |
| | | | | 15 sec | | | sec | | | | occur |
| Example 37 | H₂O₂ | 30 | 30 | DIW 15 sec + IPA | 30 | 30 | IPA 30 | 3 | 12.5 | C | Not |
| | | | | 15 sec | | | sec | | | | occur |
| Example 38 | H₂O₂ | 30 | 30 | DIW 15 sec + IPA | 30 | 30 | IPA 30 | 3 | 11.0 | B | Occur |
| | | | | 15 sec | | | sec | | | | |
| Example 39 | DIW | 30 | 30 | IPA 30 sec | 30 | 30 | IPA 30 | 3 | 11.3 | B | Not |
| | | | | | | | sec | | | | occur |
| Example 40 | DIW | 30 | 30 | IPA 30 sec | 30 | 30 | IPA 30 | 3 | 10.3 | B | Not |
| | | | | | | | sec | | | | occur |
| Example 41 | DIW | 40 | 30 | IPA 30 sec | 30 | 10 | IPA 30 | 4 | 12.5 | A | Not |
| | | | | | | | sec | | | | occur |
| Comparative | SC-1(1) | 30 | 30 | DIW 15 sec + IPA | 30 | 10 | IPA 30 | 3 | 17.3 | D | Not |
| Example 1 | | | | 15 sec | | | sec | | | | occur |
| Comparative | SC-1(1) | 30 | 30 | DIW 15 sec + IPA | 30 | 30 | IPA 30 | 3 | 25.2 | D | Not |
| Example 2 | | | | 15 sec | | | sec | | | | occur |
| Comparative | DIW | 40 | 30 | IPA 30 sec | 30 | 30 | IPA 30 | 4 | 16.3 | D | Not |
| Example 3 | | | | | | | sec | | | | occur |
| Comparative | SC-1(2) | 25 | 30 | DIW 15 sec + IPA | 30 | 30 | IPA 30 | 5 | 16.7 | D | Not |
| Example 4 | | | | 15 sec | | | sec | | | | occur |
| Comparative | DIW | 40 | 30 | IPA 30 sec | 30 | 30 | IPA 30 | 3 | 9.5 | D | Not |
| Example 5 | | | | | | | sec | | | | occur |
| Comparative | DIW | 40 | 30 | IPA 30 sec | 30 | 30 | IPA 30 | 3 | 9.5 | D | Occur |
| Example 6 | | | | | | | sec | | | | |

From the results shown in the tables, it has been confirmed that in a case where the treatment method according to an embodiment of the present invention is applied to an object to be treated having a cobalt-containing layer, a film having an excellently flat surface is obtained after the removal treatment.

It has been confirmed that in a case where the organic solvent includes propylene carbonate, an alkylene glycol monoalkyl ether, or an alkylene glycol dialkyl ether, the effect of the present invention is further improved (comparison of Examples 2, 20, 25, and 28).

It has been confirmed that in a case where the acidic compound includes an organic carboxylic acid, the effect of the present invention is further improved (comparison between Example 7 and other examples).

It has been confirmed that in a case where the content of the acidic compound in the treatment liquid is 30% by mass or less, the effect of the present invention is further improved (comparison between Example 29 and Example 37).

It has been confirmed that in a case where the content of water in the treatment liquid is 15% by mass or less, the effect of the present invention is further improved (comparison between Example 36 and Example 38). It has been confirmed that in a case where the treatment liquid substantially does not contain water, the effect of the present invention is further improved (comparison between Example 4 and Examples 12 and 40).

It has been confirmed that in a case where the total content of Ni and Cu in the treatment liquid is 10 ppb by mass or less with respect to the total mass of the treatment liquid, pitting and corrosion of the formed metal layer can be further suppressed (comparison between Example 14 and Example 15).

### EXPLANATION OF REFERENCES

10: object to be treated

12: substrate

14: insulating film

16: metal-containing substance portion

18: metal layer

20: object to be treated

What is claimed is:

1. A method for treating an object to be treated, comprising:
a step A of performing an oxidation treatment on an object to be treated having a metal layer so as to form a metal oxide layer; and
a step B of bringing a treatment liquid into contact with the object to be treated obtained by the step A so as to dissolve and remove the metal oxide layer,
wherein the treatment liquid contains an organic solvent and an acidic compound, and
a content of the organic solvent is 50% by mass or more with respect to a total mass of the treatment liquid.

2. The method for treating an object to be treated according to claim 1,
wherein the oxidation treatment is a treatment of bringing an oxidant into contact with the object to be treated having a metal layer.

3. The method for treating an object to be treated according to claim 1,
wherein the metal layer contains cobalt as a main component.

4. The method for treating an object to be treated according to claim 1,
wherein the content of the organic solvent is 70% by mass or more with respect to the total mass of the treatment liquid.

5. The method for treating an object to be treated according to claim 1,
wherein a content of water in the treatment liquid is 20% by mass or less with respect to the total mass of the treatment liquid.

6. The method for treating an object to be treated according to claim 1,
wherein a content of water in the treatment liquid is 15% by mass or less with respect to the total mass of the treatment liquid.

7. The method for treating an object to be treated according to claim 1,
wherein the treatment liquid substantially does not contain water.

8. The method for treating an object to be treated according to claim 1,
wherein a content of the acidic compound is 30% by mass or less with respect to the total mass of the treatment liquid.

9. The method for treating an object to be treated according to claim 1,
wherein the acidic compound includes an organic carboxylic acid.

10. The method for treating an object to be treated according to claim 1,
wherein the organic solvent includes a neutral organic solvent.

11. The method for treating an object to be treated according to claim 1,
wherein the organic solvent includes at least one solvent selected from the group consisting of an alcohol-based solvent, an ether-based solvent, an ester-based solvent, and a ketone-based solvent.

12. The method for treating an object to be treated according to claim 1,
wherein the organic solvent includes an alkylene glycol dialkyl ether.

13. The method for treating an object to be treated according to claim 1,
wherein a total content of Ni and Cu in the treatment liquid is 10 ppb by mass or less with respect to the total mass of the treatment liquid.

14. The method for treating an object to be treated according to claim 1,
wherein the step A is a step of performing an oxidation treatment of bringing an oxidizing liquid into contact with the object to be treated having a metal layer so as to oxidize a surface layer of the metal layer and to form the metal oxide layer.

15. The method for treating an object to be treated according to claim 14,
wherein the oxidizing liquid is at least one liquid selected from the group consisting of water, hydrogen peroxide water, a mixed aqueous solution of ammonia and hydrogen peroxide, a mixed aqueous solution of hydrofluoric acid and hydrogen peroxide water, a mixed aqueous solution of sulfuric acid and hydrogen peroxide water, a mixed aqueous solution of hydrochloric acid and hydrogen peroxide water, water containing dissolved oxygen, water containing dissolved ozone, perchloric acid, and nitric acid.

16. The method for treating an object to be treated according to claim 1,
wherein the step A and the step B are repeated.

17. A treatment liquid for an object to be treated having a metal oxide layer, the treatment liquid comprising:
an organic solvent; and
an acidic compound,
wherein a content of the organic solvent is 50% by mass or more with respect to a total mass of the treatment liquid.

18. The treatment liquid according to claim 17,
wherein the metal oxide layer contains a cobalt oxide as a main component.

19. The treatment liquid according to claim 17,
wherein the content of the organic solvent is 70% by mass or more with respect to the total mass of the treatment liquid.

20. The treatment liquid according to claim 17,
wherein a content of water in the treatment liquid is 20% by mass or less with respect to the total mass of the treatment liquid.

21. The treatment liquid according to claim 17,
wherein a content of water is 15% by mass or less with respect to the total mass of the treatment liquid.

22. The treatment liquid according to claim 17,
wherein the treatment liquid substantially does not contain water.

23. The treatment liquid according to claim 17,
wherein a content of the acidic compound is 30% by mass or less with respect to the total mass of the treatment liquid.

24. The treatment liquid according to claim 17,
wherein the acidic compound includes an organic carboxylic acid.

25. The treatment liquid according to claim 17,
wherein the organic solvent includes a neutral organic solvent.

26. The treatment liquid according to claim 17,
wherein the organic solvent includes at least one solvent selected from the group consisting of an alcohol-based solvent, an ether-based solvent, an ester-based solvent, and a ketone-based solvent.

27. The treatment liquid according to claim 17,
wherein the organic solvent includes an alkylene glycol dialkyl ether.

28. The treatment liquid according to claim 17,
wherein a total content of Ni and Cu is 10 ppb by mass or less with respect to the total mass of the treatment liquid.
